(19) United States
(12) Patent Application Publication
(10) Pub. No.: US 2026/0323968 A1
(43) Pub. Date: Oct. 15, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventor: Ming-Tsong Wang, Taipei City (TW)

(21) Appl. No.: 19/179,152

(22) Filed: Apr. 15, 2025

(51) Int. Cl. H10D 1/68; H10D 1/00; H10D 84/00; H10W 20/43

(52) U.S. Cl. CPC H10D 1/684; H10D 1/042; H10D 1/694; H10D 1/716; H10D 84/212; H10W 20/43

(57) ABSTRACT

In some embodiments, the present disclosure relates to an integrated device, including: a first electrode over a substrate; a first dielectric layer on the first electrode and having a first material with a first dielectric constant; a second dielectric layer on the first dielectric layer having a second material with a second dielectric constant, where the first dielectric constant is over five times the second dielectric constant; a third dielectric layer on the second dielectric layer having a third material with a third dielectric constant, where the third dielectric constant is over five times the second dielectric constant; and a second electrode separated from the first electrode by the first dielectric layer, the second dielectric layer, and the third dielectric layer.

### BACKGROUND

Integrated devices include a plurality of active and passive components. Passive components include resistors, capacitors, and inductors. Capacitors store charge based on their capacitance. Capacitance is a function of a surface area of a top electrode and a bottom electrode, the relative permeability of the material extending between the top electrode and the bottom electrodes, and the distance between the top electrode and the bottom electrode.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A and 1B illustrate a cross-sectional view and a band diagram of some embodiments of an integrated device having capacitor with a first insulator stack comprising a first high-k insulator, a first high band gap insulator, and a second high-k insulator.

FIGS. 2A, 2B and 2C illustrate cross-sectional views of some embodiments of an integrated device having a two dimensional capacitor with an insulator stack comprising a first high-k insulator, a first high band gap insulator, and a second high-k insulator.

FIGS. 3A-3E illustrate cross-sectional and top-down views of embodiments of an integrated device having a three dimensional capacitor with an insulator stack comprising a first high-k insulator, a first high band gap insulator, and a second high-k insulator.

FIGS. 4A-4B illustrate a cross-sectional view and a band diagram of an integrated device having capacitor with multiple sequential insulator stacks comprising a first high-k insulator, a first high band gap insulator, and a second high-k insulator.

FIGS. 5-13 illustrate cross-sectional views of some embodiments of a method of forming an integrated device having a two dimensional capacitor with an insulator stack comprising a first high-k insulator, a first high band gap insulator, and a second high-k insulator.

FIGS. 14-24 illustrate cross-sectional views of some embodiments of a method of forming an integrated device having a three dimensional capacitor with an insulator stack comprising a first high-k insulator, a first high band gap insulator, and a second high-k insulator extending into a plurality of trenches.

FIGS. 25-37 illustrate cross-sectional views of some embodiments of a method of forming an integrated device having a three dimensional capacitor with an insulator stack comprising a first high-k insulator, a first high band gap insulator, and a second high-k insulator extending into a plurality of openings.

FIG. 38 illustrates a flow diagram of some embodiments of a method of forming an integrated device having capacitor with a first insulator stack comprising a first high-k insulator, a first high band gap insulator, and a second high-k insulator.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/- 10% or +/- 5%, while in other embodiments, the terms “approximately” and/or “about” can be interpreted as meaning within the normal fabrication tolerances of a given fab manufacturing flow.

Capacitors are used in a wide variety of integrated devices, including image sensors, memory arrays, power control circuits, and more. Capacitors comprise a first electrode and a second electrode separated by a dielectric layer. Factors in the selection of a capacitor for different uses include the capacitance, size, and breakdown voltage of the capacitor. For capacitors using similar materials and structures, an improvement in one of these factors typically results in a deterioration of another of these factors. For example, in some embodiments, reducing the thickness of the dielectric layer reduces the size of the device while also reducing the breakdown voltage threshold. Similarly, choosing a material for the dielectric layer with a higher relative permeability improves the capacitance of the device while also reducing the breakdown voltage threshold. As the miniaturization of electronics and integrated devices continues, research into methods of forming more effective capacitors of smaller sizes continues apace.

In addition, several forms of emission and conduction mechanisms contribute to leakage currents and failure of capacitors, such as Poole-Frenkel emission, Schottky Emission, and hopping conduction through the dielectric layer. Poole-Frenkel emission is more prevalent in materials with higher electric fields extending through them, while Schottky emission is more dependent on the difference in band gap between different contacting layers. The conduction mechanisms contribute to the leakage and failure found in capacitors utilizing high-k insulators (e.g., materials with a relative permeability greater than 20), and result in reduced retention times for the capacitor.

In the present disclosure a variety of structural changes and material considerations are presented to produce capacitors with an improved capacitance and a reduced amount of leakage. The structural changes include using a layered dielectric stack that uses both dielectric layers with a high permeability and dielectric layers with a higher band gap, resulting in a capacitor with improved capacitance over a capacitor utilizing a high band gap dielectric layer while mitigating the current leakage associated with capacitors utilizing high relative permeability materials.

Further, the material considerations include using a material with a high work function and resistance to oxidation for the first and second electrodes. The increased work function of the electrode compared to typical materials used increases the difference in energy between the conduction band of the dielectric layer and the work function of the first and second electrodes. The increased difference in energy increases the energy necessary for Poole-Frenkel emission and Schottky emission to occur, thereby reducing leakage through the capacitor. Selecting an oxidation resistant material further reduces leakage and improves capacitance by mitigating the formation of an additional oxide layer at the interface between the first electrode and the dielectric layer. The additional oxide layer that forms on some materials (e.g., titanium nitride forming a titanium oxynitride layer) results in an increased distance between the first electrode and the second electrode, reducing the capacitance of the device. The additional oxide layer also has a conduction band between the work function of the first electrode and the conduction band of the dielectric layer, increasing the leakage current by changing the larger amount of energy used by an electron to jump from the first electrode to the dielectric layer into multiple smaller changes in energy, which makes the transmission of electrons more prevalent.

Combining the structural changes and material consideration described above results in a capacitor with higher capacitance and reduced leakage, without increasing the size of the device.

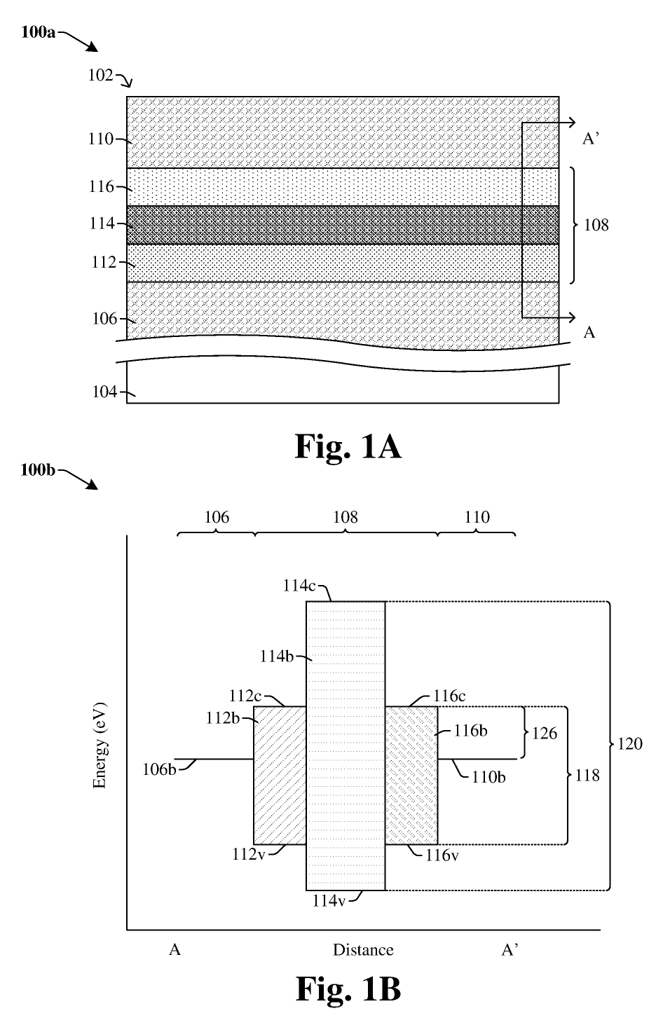

FIGS. 1A and 1B illustrate a cross-sectional view 100a and a band diagram 100b of some embodiments of an integrated device having capacitor with a first insulator stack comprising a first high-k insulator, a first high band gap insulator, and a second high-k insulator . The band diagram 100b depicts the bandgaps of layers along line A-A’ of FIG. 1A. FIGS. 1A and 1B are described concurrently.

A capacitor 102 overlies a substrate 104. The capacitor 102 comprises a first electrode 106, a first dielectric stack 108, and a second electrode 110. The first dielectric stack 108 separates the first electrode 106 from the second electrode 110. The first dielectric stack 108 comprises a first dielectric layer 112 that is or comprises a first material, a second dielectric layer 114 that is or comprises a second material, and a third dielectric layer 116 that is or comprises a third material. The first dielectric layer 112 separates the second dielectric layer 114 from the first electrode 106 and is also referred to as the first high-k insulator. The second dielectric layer 114 separates the third dielectric layer 116 from the first dielectric layer 112 and is also referred to as the first high band gap insulator. The third dielectric layer 116 separates the second electrode 110 from the second dielectric layer 114 and is also referred to as the second high-k insulator.

In some embodiments, the first material and the third material are insulative materials with a high dielectric constant (e.g., a dielectric constant that is over approximately 150). For example, in some embodiments, the first material and the third material independently are or comprise a perovskite material (e.g., a material with a perovskite crystalline structure) such as strontium titanate (SrTiO₃), barium titanate (BaTiO₃), strontium barium titanate (Sr_{w}BaₓTi_{y}O_{z}, where w is greater than or less than x, y is approximately 1, and z is approximately 3, or where a combination of w, x, and y equals approximately 2, and z is approximately 3), or the like. In some embodiments, the second dielectric layer 114 is or comprises an insulative material with a dielectric constant less than a fifth of the dielectric constants of the first dielectric layer 112 and the third dielectric layer 116. That is, the dielectric constants of the first dielectric layer 112 and the third dielectric layer 116 are over 5 times the dielectric constant of the second dielectric layer 114.

In some embodiments, the second dielectric layer 114 is or comprises zirconium oxide (ZrO₂), hafnium oxide (HfO₂), aluminum oxide (Al₂O₃), hafnium aluminum oxide, zirconium aluminum oxide, or the like. In further embodiments, the second dielectric layer 114 is or comprises an insulative material with a dielectric constant over 20 to further improve the capacitance of the resulting capacitor. In some embodiments, the first electrode 106 and the second electrode 110 are or comprise a conductive material with a work function approximately greater than 4.9. In some embodiments, the first electrode 106 and the second electrode 110 are or comprise a metal, an alloy, a conductive oxide, or the like.

As shown in the band diagram 100b of FIG. 1B, the first material of the first dielectric layer 112 has a first band gap 112b, the second material of the second dielectric layer 114 has a second band gap 114b, and the third material of the third dielectric layer 116 has a third band gap 116b. In some embodiments, the first band gap 112b has an energy difference 118 between a valence band energy 112v and a conduction band energy 112c is approximately the same as an energy difference between a valence band energy 116v and a conduction band energy 116c of the third band gap 116b. The second band gap 114b has an energy difference 120 between a valence band energy 114v and a conduction band energy 114c that is greater than the first band gap 112b and the third band gap 116b. In some embodiments, the conduction band energy 114c of the second band gap 114b is greater than the conduction band energies 112c, 116c of the first and third band gaps 112b, 116b by at least 1 electron volt.

In some embodiments, the first electrode 106 and the second electrode 110 having a work function greater than 4.9 results in a difference 126 between a fermi level 106b of the first electrode 106 and the conduction band energy 112c of the first dielectric layer 112 being at least 1 electron volt, and a difference 126 between a fermi level 110b of the second electrode 110 and conduction band energy 116c of the third dielectric layer 116 is at least 1 electron volt. Further, using a material that is an oxide or is resistant to oxidation for the first electrode 106 and the second electrode 110 prevents an additional layer from forming between the first electrode 106 and the first dielectric layer 112 during the formation of the device. The additional layer would expand the distance between the first electrode 106 and the second electrode 110, decreasing the capacitance of the capacitor 102.

Schottky emission is based on electrons gaining energy equal to a difference in the conduction band energies of the different materials. The larger (e.g., greater than 1 eV) difference between the conduction band energies 112c, 114c, 116c of the first, second, and third band gaps 112b, 114b, 116b reduces the amount of Schottky emission that occurs during operation compared to embodiments with a lower difference in conduction band energies within the first dielectric stack 108. Further, in embodiments having a difference of at least 1 eV between the fermi levels 106b, 110b of the first and second electrodes 106, 110 and the conduction band energies 112c, 116c of the first and third dielectric layers 112, 116 respectively, another barrier to Schottky emission is formed, further lowering the current leakage through the capacitor 102.

While the height of the second band gap mitigates the amount of current leakage that occurs through the device, the high (e.g., greater than 150) dielectric constant of the first and third materials in the first and third dielectric layers 112, 116 increases the effective dielectric constant (e.g., the dielectric constant of the first dielectric stack 108). In some embodiments, the effective dielectric constant of the first dielectric stack is over 50% greater than the dielectric constant of the second material. Therefore, the first dielectric stack 108 of the capacitor 102 described in relation to FIGS. 1A and 1B offers improvements to the capacitance of a capacitor without increasing the size or significantly increasing the current leakage across the capacitor 102, while the differences in fermi level and conduction band energies of the described layers further reduces the leakage of the capacitor 102. The increased capacitance and improved leakage protection result in a capacitor with improved performance.

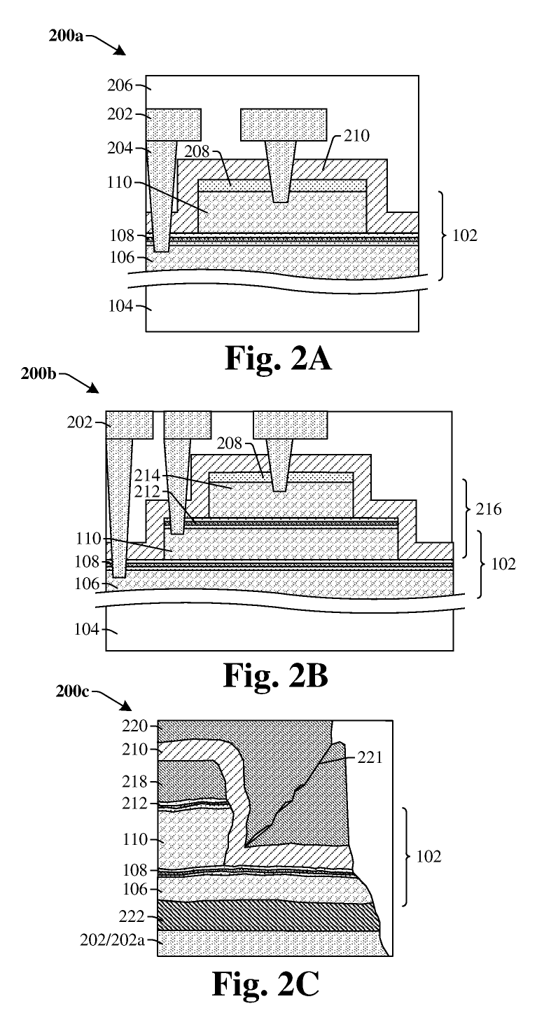

FIGS. 2A, 2B and 2C illustrate cross-sectional views 200a, 200b, 200c of some embodiments of an integrated device having a two dimensional capacitor with an insulator stack comprising a first high-k insulator, a first high band gap insulator, and a second high-k insulator .

As shown in the cross-sectional view 200a of FIG. 2A, in some embodiments, the first electrode 106, the first dielectric stack 108, and the second electrode 110 are approximately flat (e.g., upper and lower surfaces of the first electrode 106, the first dielectric stack 108, and the second electrode 110 have heights above the substrate 104 that vary by less than 10%). In some embodiments, the first electrode 106 and the first dielectric stack 108 have a width that is greater than a width of the second electrode 110. An interconnect structure 202 extends over the capacitor 102 and is coupled to the first electrode 106 and the second electrode 110 using contacts 204. The interconnect structure 202 is surrounded by an interlayer dielectric 206. In some embodiments, a first capping layer 208 covers a top surface of the second electrode 110. A passivation layer 210 covers the capacitor, separating the first electrode 106, the first dielectric stack 108, and the second electrode 110 from the interlayer dielectric 206.

As shown in the cross-sectional view 200b of FIG. 2B, in some embodiments, a second dielectric stack 212 extends over the second electrode 110, and a third electrode 214 is separated from the second electrode 110 by the second dielectric stack 212. In some embodiments, the first capping layer 208 covers a top surface of the third electrode 214. In some embodiments, the third electrode 214 and the first electrode 106 are coupled together by the interconnect structure 202, resulting in the capacitor 102 having a greater capacitance than an identical capacitor where the third electrode 214 is omitted. In other embodiments, the third electrode 214 is not coupled to the first electrode 106, and the second electrode 110, second dielectric stack 212, and the third electrode 214 together make up a second capacitor 216.

As shown in the cross-sectional view 200c of FIG. 2C, in some embodiments, a first insulative layer 218 extends over a top surface of the second dielectric stack 212, between the second dielectric stack 212 and the passivation layer 210. In some embodiments, the first insulative layer 218 is an extension of the first capping layer 208. In some embodiments, a protective layer 220 covers the capacitor 102. In further embodiments, the method of forming the protective layer 220 results in a seam 221 in the layer extending from an inner corner of the passivation layer 210. In some embodiments, the first electrode 106 is coupled to the interconnect structure 202 through a underlying wire 202a directly beneath the first electrode 106. In further embodiments, a conductive glue layer 222 separates the first electrode 106 from the underlying wire 202a. The conductive glue layer 222 improves the adhesion of the first electrode 106 to the underlying wire 202a while preventing material from the underlying wire 202a from diffusing into the first electrode 106. In other embodiments, the first electrode 106 is coupled to the interconnect structure 202 through a contact (see 204 of FIG. 2A) extending through the top of the first electrode 106, and the conductive glue layer 222 extends between the first electrode 106 and an underlying insulative layer (not shown), adhering the first electrode 106 to the underlying insulative layer.

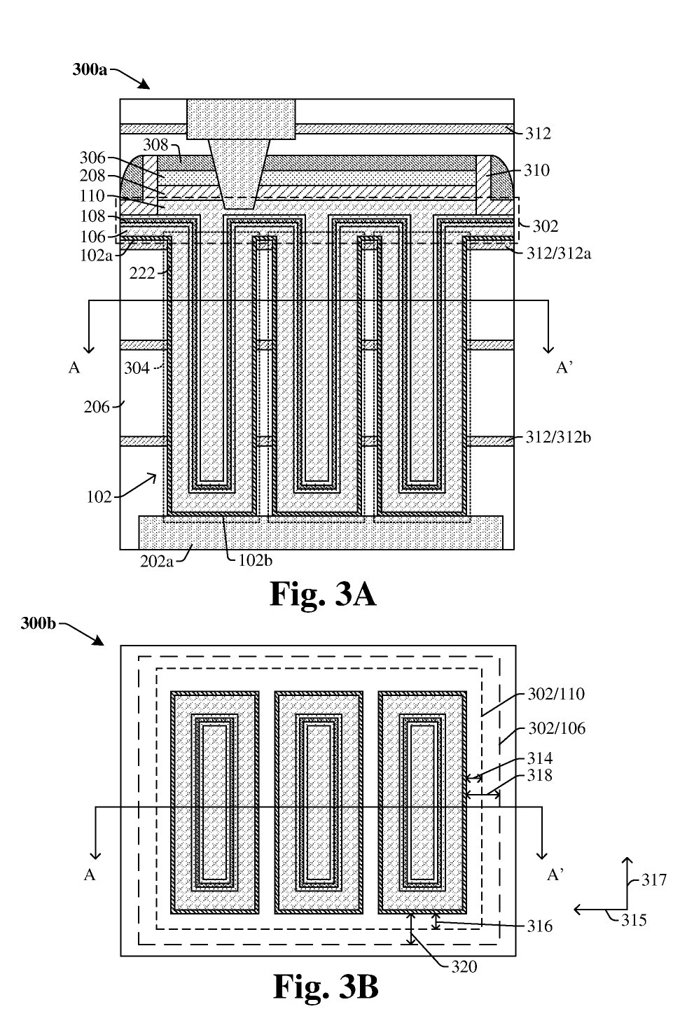

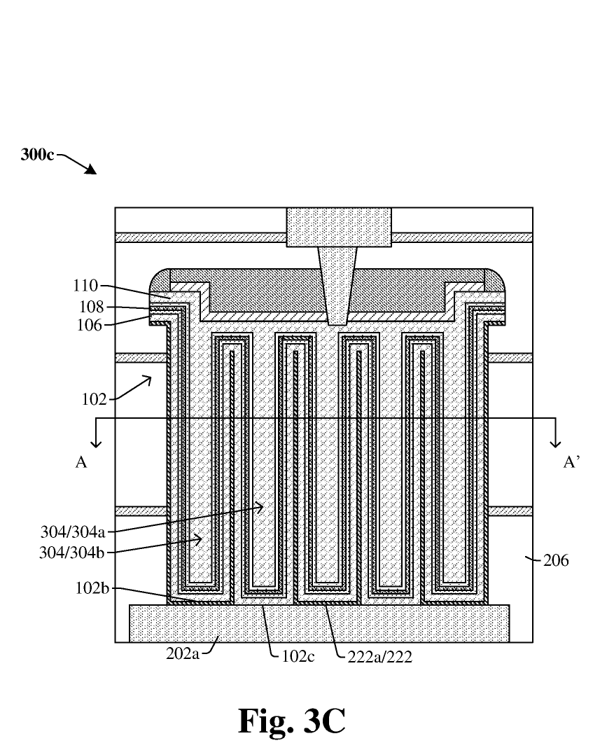

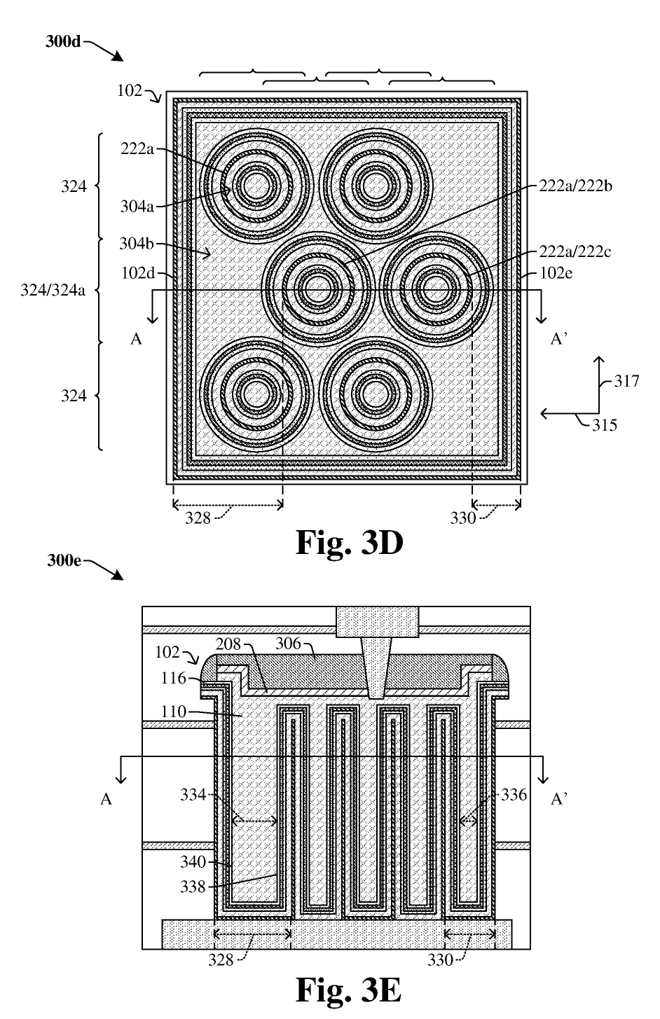

FIGS. 3A-3E illustrate cross-sectional views 300a, 300c, 300e and top-down views 300b, 300d of embodiments of an integrated device having a three dimensional capacitor with an insulator stack comprising a first high-k insulator, a first high band gap insulator, and a second high-k insulator. FIGS. 3A and 3B are described concurrently. The cross-sectional view 300a of FIG. 3A is taken along line A-A’ of the top-down view 300b of FIG. 3B. The cross-sectional view 300c of FIG. 3C is taken along line A-A’ of the top-down view 300d of FIG. 3D. The cross-sectional view 300e of FIG. 3E is an alternative to the cross-sectional view 300c of FIG. 3C and is taken along line A-A’ of the top-down view 300d of FIG. 3D.

As shown in the cross-sectional view 300a and the top-down view 300b, in some embodiments, the capacitor 102 comprises a base portion 302 and a plurality of sleeve portions 304 extending from a first lower surface 102a of the base portion 302. Second lower surfaces 102b of the sleeve portions 304 extend to and are electrically coupled to the underlying wire 202a. The conductive glue layer 222, the first electrode 106, the first dielectric stack 108, and the second electrode 110 extend from the base portion 302 and into the sleeve portions 304. The interlayer dielectric 206 surrounds and extends between the sleeve portions 304. In some embodiments, the interlayer dielectric 206 comprises a plurality of etch stop layers 312. In further embodiments, the sleeve portions 304 extend from a first etch stop layer 312a to the underlying wire 202a through one or more additional etch stop layers 312b of the plurality of etch stop layers 312.

In some embodiments, a second capping layer 306 and a third capping layer 308 cover the second electrode 110 along with the first capping layer 208. The first, second, and third capping layers 208, 306, 308 are surrounded by an insulative spacer 310 that spaces outer sidewalls of the second electrode 110 from outer sidewalls of the first electrode 106 and the first dielectric stack 108. In some embodiments, the insulative spacer 310 is or comprises a plurality of layers with different insulative materials.

In some embodiments, the sleeve portions 304 extend along trenches in the interlayer dielectric 206. The portions of the second electrode 110 in the base portion 302 extend past outer sidewalls of the sleeve portions 304 for a first distance 314 in a first direction 315 and for a second distance 316 in a second direction 317. Portions of the first electrode in the base portion 302 extend past outer sidewalls of the sleeve portions for a third distance 318 in the first direction 315 and for a fourth distance 320 in the second direction 317. In some embodiments, the first distance 314 is the same as the second distance 316. In other embodiments, the first distance is different from the second distance 316. In some embodiments, a difference between the third distance 318 and the first distance 314 is substantially equal to a difference between the fourth distance 320 and the second distance 316.

As shown in the cross-sectional view 300c of FIG. 3C, in some embodiments, the sleeve portions 304 comprise a second sleeve portion 304b having a second lower surface 102b and a first plurality of cylindrical sleeve portions 304a having third lower surfaces 102c. The second sleeve portion 304b surrounds the first plurality of cylindrical sleeve portions 304a. In some embodiments, the second lower surface 102b is coupled to the underlying wire 202a through the conductive glue layer 222. In further embodiments, the third lower surfaces 102c extend beneath the second lower surface 102b and contact the underlying wire 202a directly. The conductive glue layer 222 comprises a plurality of cylindrical structures 222a surrounding the third lower surfaces 102c and extending upwards from the second lower surface 102b.

As shown in the top-down view 300d of FIG. 3D, in some embodiments, the first plurality of cylindrical sleeve portions 304a having the third lower surfaces 102c have a circular profile when view from a top down perspective. In some embodiments, a portion of the second electrode 110 within the second sleeve portion 304b and surrounding the first plurality of cylindrical sleeve portions 304a has a nonuniform thickness. The second sleeve portion 304b has the second lower surface 102b. In some embodiments, the second sleeve portion 304b extends between the first plurality of cylindrical sleeve portions 304a, separating the third lower surfaces 102c from one another.

The first electrode 106, the first dielectric stack 108, and the second electrode 110 extend along inner and outer sidewalls of the cylindrical structures 222a, resulting in an improved capacitor surface area. In some embodiments, the cylindrical structures 222a are arranged in a plurality of rows 324 extending in the first direction 315 and a plurality of overlapping columns 326 extending in the second direction 317. In some embodiments, the cylindrical structures 222a of a first row 324a of the plurality of rows 324 comprise a first cylindrical structure 222b in a first column 326a of the plurality of overlapping columns 326 and a second cylindrical structure 222c in a second column 326b of the plurality of overlapping columns 326. In further embodiments, the first cylindrical structure 222b is a first distance 328 in the first direction 315 from a first outer sidewall 102d of the capacitor 102 nearest to the first cylindrical structure 222b. Further, the second cylindrical structure 222c is a second distance 330 in the first direction 315 from a second outer sidewall 102e of the capacitor 102 nearest to the second cylindrical structure 222c, where the first distance 328 is different from the second distance 330. The difference between the first distance 328 and the second distance 330 is a result of differences between the rectangular top-down profile of the capacitor 102 and the positioning of the cylindrical structures 222a in overlapping columns 326.

As shown in the cross-sectional view 300e of FIG. 3E, in some embodiments, the difference between the first distance 328 and the second distance 330 is small enough that the deposition process (see FIG. 32) used to form the second electrode 110 results in the portion of the second electrode 110 extending directly between the first cylindrical structure 222b and the first outer sidewall 102d nearest to it having a first thickness 334. Further, the portion of the second electrode 110 extending directly between the second cylindrical structure 222c and the second outer sidewall 102e nearest to it has a second thickness 336 that is less than the first thickness 334. In other embodiments, differences in the first distance 328 and the second distance 330 are larger, resulting in the second electrode 110 not filling the space between a first inner sidewall 338 of the third dielectric layer 116 extending over the first cylindrical structure 222b and a second inner sidewall 340 of the third dielectric layer 116 extending over the first outer sidewall 102d nearest to the first cylindrical structure 222b. Instead, the first capping layer 208 and/or the second capping layer 306 extend directly between the first inner sidewall 338 and the second inner sidewall 340, filling the intervening space.

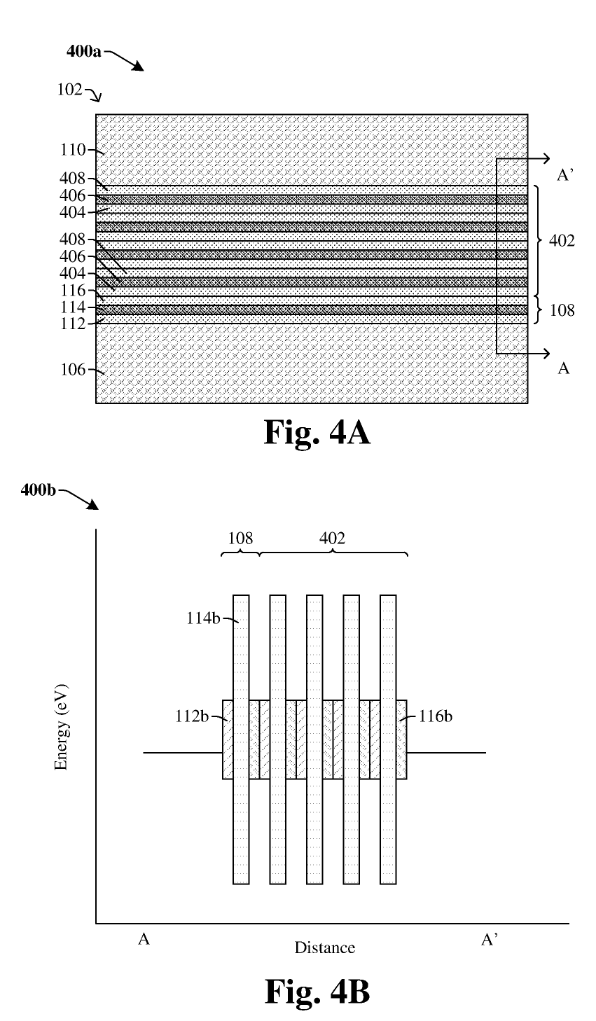

FIGS. 4A-4B illustrate a cross-sectional view 400a and a band diagram 400b of an integrated device having capacitor with a plurality if additional dielectric stacks comprising additional first high-k insulators, additional first high band gap insulators, and additional second high-k insulators. The band diagram 400b depicts the bandgaps of layers along line A-A’ of FIG. 4A. FIGS. 4A and 4B are described concurrently.

In some embodiments, a plurality of additional dielectric stacks 402 having a same order of layers as the first dielectric stack 108 extend between the first electrode 106 and the second electrode 110. That is, in some embodiments, a repeating group of dielectric layers comprising an additional first dielectric layer 404 substantially the same thickness and material as the first dielectric layer 112, an additional second dielectric layer 406 substantially the same thickness and material as the second dielectric layer 114, and an additional third dielectric layer 408 substantially the same thickness and material as the third dielectric layer 116 are formed over the first dielectric stack 108. For example, in some embodiments, the first dielectric stack 108 comprises the first dielectric layer 112, the second dielectric layer 114, and the third dielectric layer 116 respectively having thicknesses between approximately 1 angstrom and 50 angstroms. An additional first dielectric layer 404 overlies the third dielectric layer 116, an additional second dielectric layer 406 overlies the additional first dielectric layer 404, and an additional third dielectric layer 408 overlies the additional second dielectric layer 406. In some embodiments, the materials of the additional first dielectric layers 404, the additional second dielectric layers 406, and the additional third dielectric layers 408 are or comprise the first material, the second material, and the third material, respectively.

The first dielectric layer 112 and the additional first dielectric layers 404 have the first band gap 112b and the first dielectric constant. The second dielectric layer 114 and the additional second dielectric layers 406 have the second band gap 114b and the second dielectric constant. The third dielectric layer 116 and the additional third dielectric layers 408 have the third band gap 116b and the third dielectric constant. Having multiple layers with the second band gap 114b separated by multiple layers of the first band gap 112b and multiple layers of the third band gap 116b results in greater mitigation of leakage due to Schottky emission, as the electrons would have to gain enough energy to reach the conduction band in the second bandgap multiple times to pass through the capacitor 102.

The first dielectric layer 112 and the additional first dielectric layers 404 have approximately the same effect on the effective dielectric constant to a single dielectric layer of the first material and a same total thickness. Similarly, the third dielectric layer 116 and the additional third dielectric layers 408 have approximately the same effect on the effective dielectric constant to a single dielectric layer of the third material and a same total thickness. Therefore, embodiments using a plurality of additional dielectric stacks 402 have a further reduced amount of leakage and approximately the same effective dielectric constant to embodiments with a single dielectric stack (e.g., the first dielectric stack 108 shown in FIG. 1A), where the total thickness of dielectric layers having the first material, the total thickness of dielectric layers having the second material, and the total thickness of dielectric layers having the third material is the same between both embodiments.

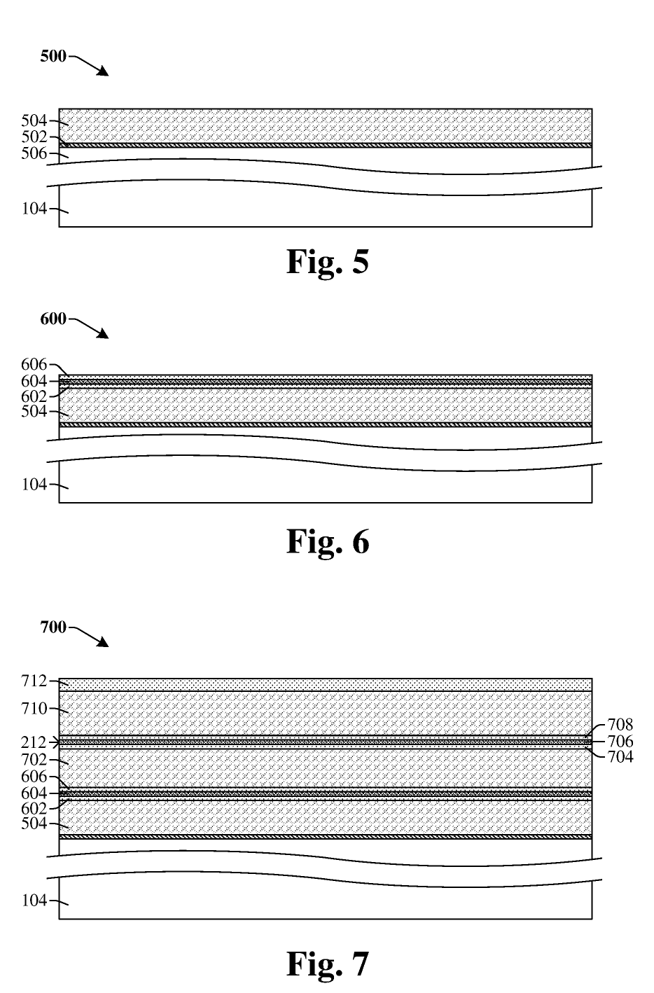

FIGS. 5-13 illustrate cross-sectional views 500-1300 of some embodiments of a method of forming an integrated device having a two dimensional capacitor with an insulator stack comprising a first high-k insulator, a first high band gap insulator, and a second high-k insulator. Although FIGS. 5-13 are described in relation to a method, it will be appreciated that the structures disclosed in FIGS. 5-13 are not limited to such a method, but instead may stand alone as structures independent of the method.

As shown in cross-sectional view 500 of FIG. 5, a conformal conductive glue layer 502 and a first conductive layer 504 are formed over the substrate 104. In some embodiments, the conformal conductive glue layer 502 is formed over an underlying insulative layer 506. In some embodiments, the first conductive layer 504 is or comprises a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the first conductive layer 504 has a thickness approximately between 50 to 400 angstroms, between 150 and 500 angstroms, between 50 and 500 angstroms, or within another similar range.

In some embodiments, the conformal conductive glue layer 502 is or comprises one or more of tantalum (Ta), tantalum nitride (TaN), or the like. In some embodiments, the underlying insulative layer 506 is or comprises an insulative material, such as silicon dioxide, undoped silicate glass (USG), silicon nitride (Si₃N₄), or the like. In some embodiments, the conformal conductive glue layer 502 and the first conductive layer 504 are formed using a deposition process, such as atomic layer deposition (ALD), physical vapor deposition (PVD), chemical vapor deposition (CVD), or the like.

As shown in cross-sectional view 600 of FIG. 6, a first conformal dielectric layer 602, a second conformal dielectric layer 604, and a third conformal dielectric layer 606 are formed over the first conductive layer 504. In some embodiments, the first conformal dielectric layer 602 and the third conformal dielectric layer 606 independently are or comprise an insulative materials with a high dielectric constant (e.g., a dielectric constant that is over approximately 150), such as strontium titanate (Sr_{w}Ti_{y}O_{z}, where w is approximately 1, y is approximately 1, and z is approximately 3, where a combination of w and y is approximately 2 and z is approximately 3, or another ratio of strontium, titanium, and oxygen), barium titanate (BaₓTi_{y}O_{z}, where x is approximately 1, y is approximately 1, and z is approximately 3, or where a combination of x and y is approximately 2 and z is approximately 3, or another ratio of barium, titanium, and oxygen), strontium barium titanate (Sr_{w}BaₓTi_{y}O_{z}, where w is greater than or less than x, y is approximately 1, and z is approximately 3, or where a combination of w, x, and y is approximately 2 and z is approximately 3, or another ratio of strontium, barium, titanium, and oxygen), or the like. In some embodiments, the second conformal dielectric layer 604 is or comprises an insulative material with a dielectric constant less than a fifth of the dielectric constants of the first conformal dielectric layer 602 and the third conformal dielectric layer 606, such as zirconium oxide (ZrO₂), hafnium oxide (HfO₂), aluminum oxide (Al₂O₃), hafnium aluminum oxide, zirconium aluminum oxide, or the like. In some embodiments, the first conformal dielectric layer 602, the second conformal dielectric layer 604, and the third conformal dielectric layer 606 are formed using a deposition process, such as ALD, PVD, CVD, or the like.

In some embodiments, the first conformal dielectric layer 602 has a thickness approximately between 1 to 80 angstroms, between 30 and 100 angstroms, between 1 and 100 angstroms, or within another similar range. In some embodiments, the second conformal dielectric layer 604 has a thickness approximately between 1 to 40 angstroms, between 10 and 50 angstroms, between 1 and 50 angstroms, or within another similar range. In some embodiments, the third conformal dielectric layer 606 has a thickness approximately between 1 to 80 angstroms, between 30 and 100 angstroms, between 1 and 100 angstroms, or within another similar range.

As shown in cross-sectional view 700 of FIG. 7, in some embodiments, pursuant to forming a multi metal-insulator-metal capacitor with first, second, and third electrodes (see 106, 110, and 214 of FIG. 2B), a second conductive layer 702, a fourth conformal dielectric layer 704, a fifth conformal dielectric layer 706, a sixth conformal dielectric layer 708, and a third conductive layer 710 are formed over the third conformal dielectric layer 606. In other embodiments, pursuant to forming a single metal-insulator-metal capacitor with first and second electrodes (see 106 and 110 of FIG. 2A), a second conductive layer 702 is formed over the third conformal dielectric layer 606 without forming the second dielectric stack 212 or the third conductive layer 710. A first conformal capping layer 712 is formed over the exposed conductive layer.

In some embodiments, the second conductive layer 702 and the third conductive layer 710 independently are or comprise a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the fourth conformal dielectric layer 704 and the sixth conformal dielectric layer 708 independently are or comprise an insulative materials with a high dielectric constant (e.g., a dielectric constant that is over approximately 150), such as strontium titanate (Sr_{w}Ti_{y}O_{z}, as described in relation to FIG. 6), barium titanate (BaₓTi_{y}O_{z}, as described in relation to FIG. 6), strontium barium titanate (Sr_{w}BaₓTi_{y}O_{z}, as described in relation to FIG. 6), or the like. In some embodiments, the fifth conformal dielectric layer 706 is or comprises an insulative material with a dielectric constant less than a fifth of the dielectric constants of the fourth conformal dielectric layer 704 and the sixth conformal dielectric layer 708, such as zirconium oxide (ZrO₂), hafnium oxide (HfO₂), aluminum oxide (Al₂O₃), hafnium aluminum oxide, zirconium aluminum oxide, or the like. In some embodiments, the first conformal capping layer 712 is or comprises an insulative material, such as silicon nitride (Si₃N₄), silicon oxynitride, or the like.

In some embodiments, the second conductive layer 702 and the third conductive layer 710 have thicknesses within the same range as the range of thicknesses for the first conductive layer 504. In some embodiments, the fourth conformal dielectric layer 704 and the sixth conformal dielectric layer 708 respectively have thicknesses within the same range as the range of thicknesses for the first conformal dielectric layer 602 and the third conformal dielectric layer 606. In some embodiments, the fifth conformal dielectric layer 706 has a thickness within the same range as the range of thicknesses describe for the second conformal dielectric layer 604. In some embodiments, the second conductive layer 702, the fourth conformal dielectric layer 704, the fifth conformal dielectric layer 706, the sixth conformal dielectric layer 708, and the third conductive layer 710 are independently formed using deposition processes, such as ALD, PVD, CVD, or the like.

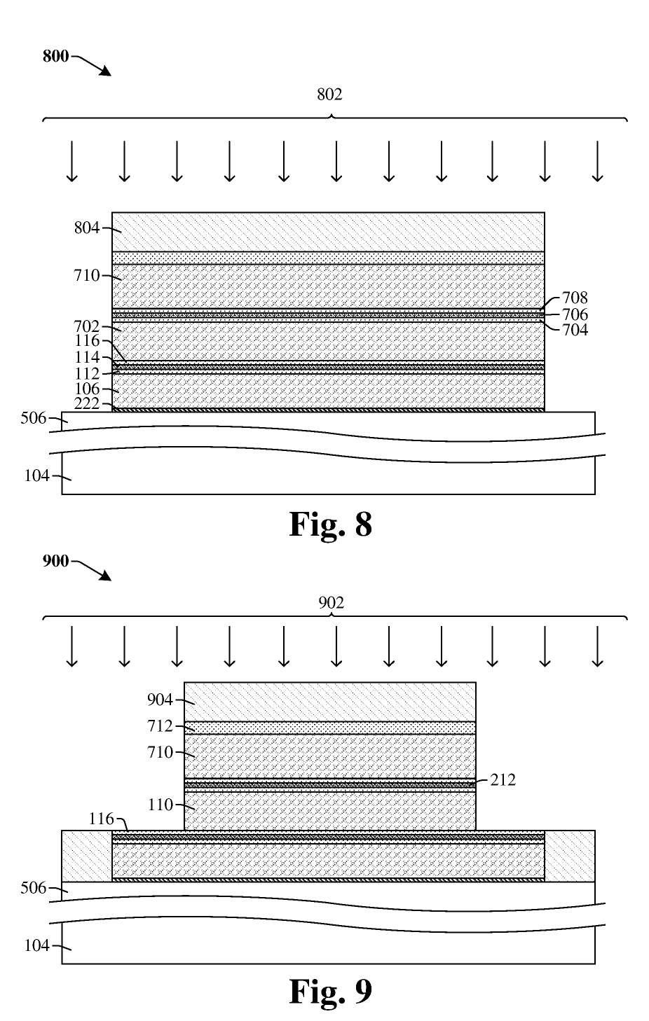

As shown in cross-sectional view 800 of FIG. 8, a first masking layer 804 is formed over the substrate 104. In some embodiments, the first masking layer 804 is or comprises a photoresist, hard mask, or the like. In some embodiments, the first masking layer is formed using a deposition process, dipping process, spin-on process, sputtering process, or the like. The first masking layer 804 is subsequently patterned to cover an area of the first conductive layer (see 504 of FIG. 5) corresponding to the area of the first electrode 106 to be formed hereafter and to expose portions of the first conformal capping layer 712 surrounding the location of the first electrode 106. In some embodiments, the first masking layer 804 is patterned using an etching process, photolithography, or the like.

After the first masking layer 804 is patterned, a first etching process 802 is performed. The first etching process 802 removes portions of the conformal conductive glue layer (see 502 of FIG. 5), the first conductive layer (see 504 of FIG. 5), the first conformal dielectric layer (see 602 of FIG. 6), the second conformal dielectric layer (see 604 of FIG. 6), the third conformal dielectric layer (see 606 of FIG. 6), the second conductive layer 702, the fourth conformal dielectric layer 704, the fifth conformal dielectric layer 706, the sixth conformal dielectric layer 708, and the third conductive layer 710 that extend past outer sidewalls of the first electrode 106 and the first masking layer 804. The first etching process 802 also exposes the underlying insulative layer 506. In some embodiments, the first etching process 802 is or comprises an anisotropic dry etching process. The first masking layer 804 is subsequently removed.

As shown in cross-sectional view 900 of FIG. 9, a second masking layer 904 is formed over the first conformal capping layer 712 and the exposed portions of the underlying insulative layer 506. In some embodiments, the second masking layer 904 is or comprises a photoresist, hard mask, or the like. In some embodiments, the second masking layer 904 is formed using a deposition process, dipping process, spin-on process, sputtering process, or the like. The second masking layer 904 is subsequently patterned to cover an area of the second conductive layer (see 702 of FIG. 7) corresponding to the area of the second electrode 110 and to expose surrounding portions of the second conductive layer (see 702 of FIG. 7). In some embodiments, the second masking layer 904 is patterned using an etching process, photolithography, or the like.

After the second masking layer 904 is patterned, a second etching process 902 is performed. The second etching process 902 removes portions of the second conductive layer (see 702 of FIG. 7), the fourth conformal dielectric layer (see 704 of FIG. 7), the fifth conformal dielectric layer (see 706 of FIG. 7), the sixth conformal dielectric layer (see 708 of FIG. 7), and the third conductive layer 710 that extend past outer sidewalls of the second masking layer 904 and the second electrode 110. The second etching process 902 also exposes a top surface of the third dielectric layer 116. In some embodiments, the second etching process 902 is or comprises an anisotropic dry etching process. The second masking layer 904 is subsequently removed.

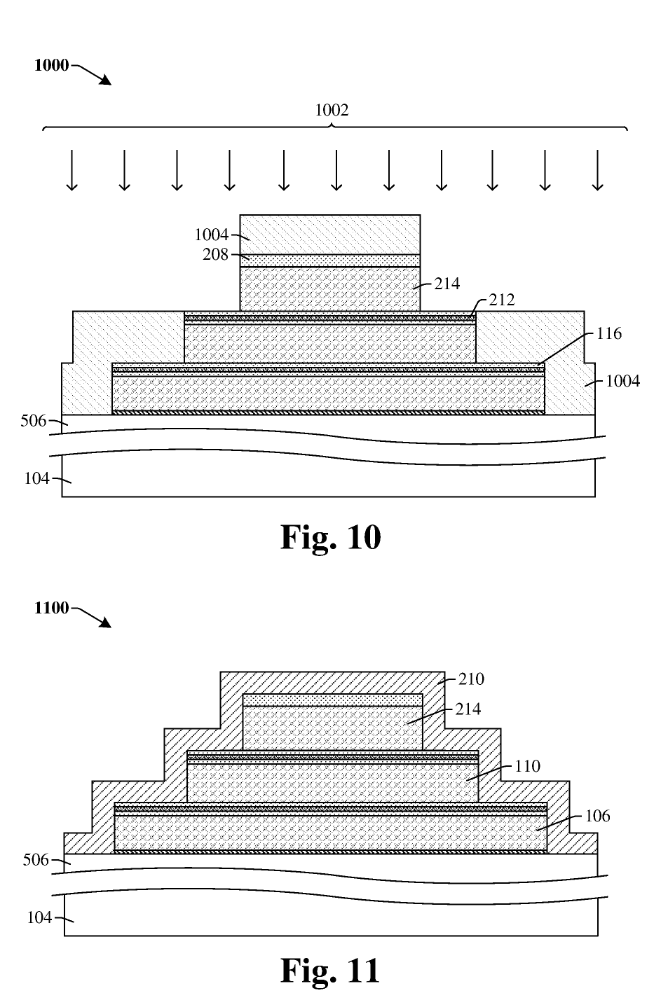

As shown in cross-sectional view 1000 of FIG. 10, in embodiments having a third conductive layer (see 710 of FIG. 7), a third masking layer 1004 is formed over the first conformal capping layer (see 712 of FIG. 9) and the exposed portions of the underlying insulative layer 506 and third dielectric layer 116. In some embodiments, the third masking layer 1004 is or comprises a photoresist, hard mask, or the like. In some embodiments, the third masking layer 1004 is formed using a deposition process, dipping process, spin-on process, sputtering process, or the like. The third masking layer 1004 is subsequently patterned to cover an area of the third conductive layer (see 710 of FIG. 7) corresponding to the area of the third electrode 214 and to expose surrounding portions of the second conductive layer (see 702 of FIG. 7). In some embodiments, the third masking layer 1004 is patterned using an etching process, photolithography, or the like.

After the third masking layer 1004 is patterned, a third etching process 1002 is performed. The third etching process 1002 removes portions of the third conductive layer (see 710 of FIG. 9) and the first conformal capping layer (see 712 of FIG. 9) that extend past outer sidewalls of the third masking layer 1004 and the third electrode 214. The third etching process 1002 also exposes a top surface of the second dielectric stack 212. In some embodiments, the third etching process 1002 is or comprises an anisotropic dry etching process. The third masking layer 1004 is subsequently removed. In embodiments where the third conductive layer 710 is omitted, steps represented in FIG. 10 are omitted as well.

In other embodiments, as an alternative to the method described in relation to FIGS. 8, 9, and 10, the areas covered by the masking layers of FIGS. 8, 9, and 10 are altered as described. The area covered by the first masking layer (see 804 of FIG. 8) corresponds to the area of the third electrode 214, which remains after the first etching step (see 802 of FIG. 8). The first etching step (see 802 of FIG. 8) does not etch through the second dielectric stack (see 212 of FIG. 2B). Further, the area covered by the second masking layer (see 904 of FIG. 9) corresponds to the area of the second electrode (see 110 of FIG. 2B) and covers the third electrode 214, and the second electrode (see 110 of FIG. 2B) remains after the second etching step (see 902 of FIG. 9). The second etching step (see 902 of FIG. 9) does not etch through the first dielectric stack (see 108 of FIG. 2B). Further, the area covered by the third masking layer 1004 corresponds to the area of the first electrode (see 106 of FIG. 2B) and covers the second electrode (see 110 of FIG. 2B) and the third electrode 214, and the first electrode (see 106 of FIG. 2B) remains after the third etching step (see 1002 of FIG. 10).

As shown in cross-sectional view 1100 of FIG. 11, a passivation layer 210 is formed over the first, second, and third electrodes 106, 110, 214. In some embodiments, the passivation layer 210 is or comprises an insulative material, such as silicon dioxide (SiO₂), silicon nitride (Si₃N₄), or the like. The passivation layer is formed using a deposition process, such as ALD, PVD, CVD, or the like.

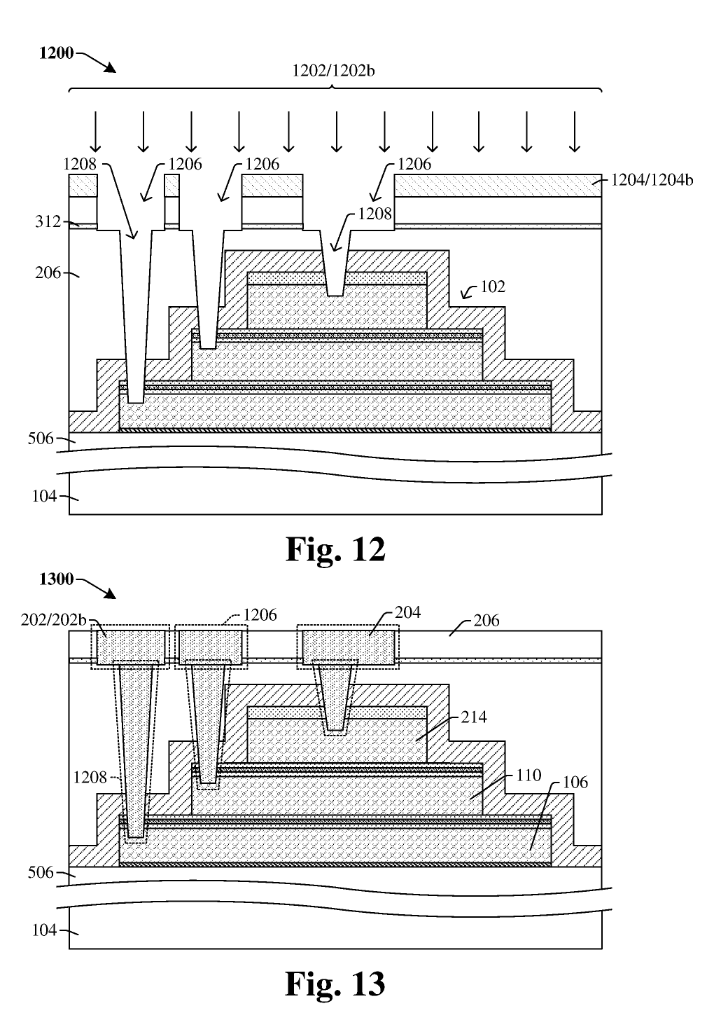

As shown in cross-sectional view 1200 of FIG. 12, an interlayer dielectric 206 is deposited over the capacitor 102, and a first wire openings 1206 and first via openings 1208 are subsequently etched into the interlayer dielectric 206, exposing the first, second, and third electrodes 106, 110, 214. In some embodiments, the interlayer dielectric 206 is or comprises an insulative material, such as USG, silicon dioxide (SiO₂), or the like. In some embodiments, etch stop layers 312 within the interlayer dielectric 206 are or comprise an insulative material, such as silicon nitride (Si₃N₄), silicon oxynitride, or the like. The interlayer dielectric 206 and the etch stop layers 312 are formed using deposition processes, such as ALD, PVD, CVD, or the like.

After the interlayer dielectric 206 is formed, a plurality of fourth etching processes 1202 are performed. The plurality of fourth etching processes 1202 are performed according to a plurality of fourth masking layers 1204, resulting in first wire openings 1206 and the first via openings 1208. In some embodiments, a first mask (not shown) of the plurality of fourth masking layers 1204 is formed and patterned to expose portions of the interlayer dielectric 206 corresponding to the first via openings 1208. A first etch (not shown) of the plurality of fourth etching processes 1202 is performed to then form a portion of the first via openings 1208. The first mask is removed, and a second mask 1204b of the plurality of fourth masking layers 1204 is formed and patterned to expose portions of the interlayer dielectric 206 corresponding to the locations of the first wire openings 1206. A second etch 1202b of the plurality of fourth etching processes 1202 is performed to then form the remaining portion of the first via openings 1208 and the first wire openings 1206. In some embodiments, sacrificial plugs (not shown) are formed in the first via openings 1208 to reduce the effect of the second etch 1202b on the underlying first, second, and third electrodes 106, 110, 214. The second mask 1204b is subsequently removed.

As shown in cross-sectional view 1300 of FIG. 13, the contacts 204 and an overlying wire 202b of the interconnect structure is formed in the first via openings 1208 (shown in phantom) and the first wire openings 1206 (shown in phantom). In some embodiments, the contacts 204 and an overlying wire 202b are formed using a deposition process such as ALD, PVD, CVD, or the like to form a conformal metal layer (not shown), then performing a planarization process (e.g., a chemical mechanical planarization (CMP) process to remove portions of the conformal metal layer extending over the interlayer dielectric 206. In some embodiments, the contacts 204 and an overlying wire 202b are or comprise a conductive metal, such as copper (Cu), tungsten (W), aluminum (Al), or the like. In some embodiments, a second conductive glue layer (not shown) is deposited before the conformal metal layer to separate the material of the contacts 204 and the overlying wire 202b from the first, second, and third electrodes 106, 110, 214.

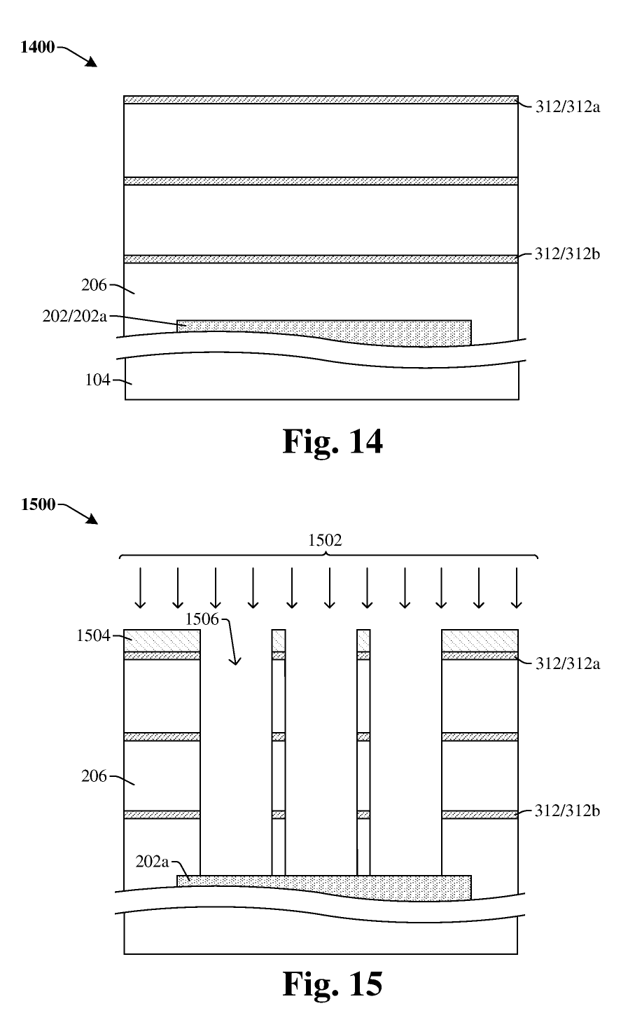

FIGS. 14-24 illustrate cross-sectional views 1400-2400 of some embodiments of a method of forming an integrated device having a three dimensional capacitor with an insulator stack comprising a first high-k insulator, a first high band gap insulator, and a second high-k insulator extending into a plurality of trenches. Although FIGS. 14-24 are described in relation to a method, it will be appreciated that the structures disclosed in FIGS. 14-24 are not limited to such a method, but instead may stand alone as structures independent of the method.

As shown in cross-sectional view 1400 of FIG. 14, an interlayer dielectric 206 and a plurality of etch stop layers 312 are formed over an underlying wire 202a of the interconnect structure 202 on a substrate 104. The plurality of etch stop layers 312 comprise a first etch stop layer 312a overlying the interlayer dielectric 206 and a plurality of additional etch stop layers 312b extending through the interlayer dielectric 206. In some embodiments, the interlayer dielectric 206 is or comprises an insulative material, such as USG, silicon dioxide (SiO₂), or the like. In some embodiments, the plurality of etch stop layers 312 within the interlayer dielectric 206 are or comprise an insulative material, such as silicon nitride (Si₃N₄), silicon oxynitride, or the like. The interlayer dielectric 206 and the plurality of etch stop layers 312 are formed using deposition processes, such as ALD, PVD, CVD, or the like.

As shown in cross-sectional view 1500 of FIG. 15, a fourth masking layer 1504 is formed over the first etch stop layer 312a. In some embodiments, the first masking layer 804 is or comprises a photoresist, hard mask, or the like. In some embodiments, the fourth masking layer 1504 is formed using a deposition process, dipping process, spin-on process, sputtering process, or the like. The fourth masking layer 1504 is subsequently patterned to expose portions of the first etch stop layer 312a corresponding to the location of the sleeve portions (see 304 of FIG. 3A) to be formed hereafter. In some embodiments, the fourth masking layer 1504 is patterned using an etching process, photolithography, or the like.

After the fourth masking layer 1504 is patterned, a fourth etching process 1502 is performed. The fourth etching process 1502 removes portions of the first etch stop layer 312a, the plurality of additional etch stop layers 312b, and the interlayer dielectric 206 beneath the exposed portions of the first etch stop layer 312a, forming first openings 1506. The fourth etching process 1502 also exposes the underlying wire 202a. In some embodiments, the first etching process 802 is or comprises an anisotropic dry etching process. The fourth masking layer 1504 is subsequently removed.

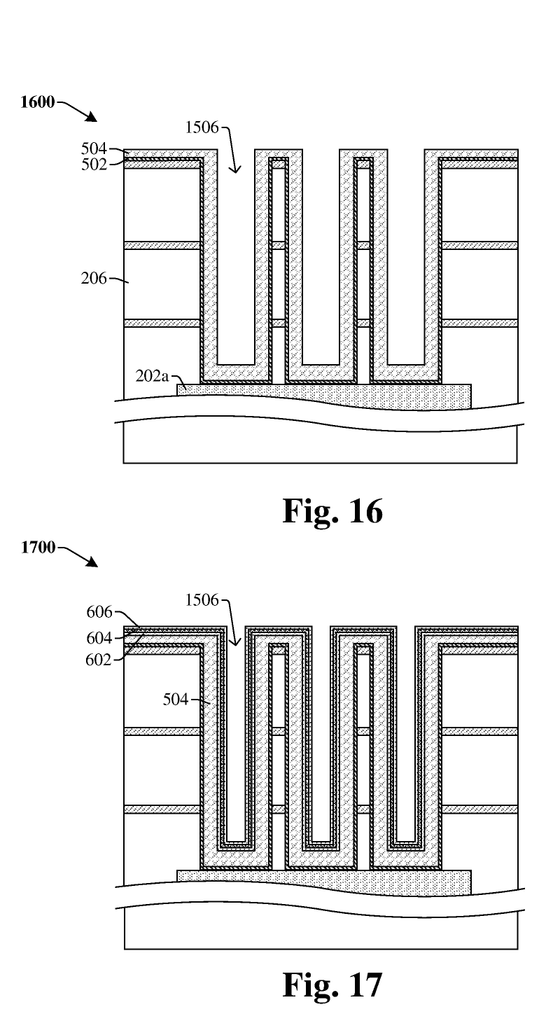

As shown in cross-sectional view 1600 of FIG. 16, the conformal conductive glue layer 502 and the first conductive layer 504 are formed over the interlayer dielectric 206 and in the first openings 1506. The conformal conductive glue layer 502 contacts the underlying wire 202a. In some embodiments, the first conductive layer 504 is or comprises a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the first conductive layer 504 has a thickness approximately between 50 to 400 angstroms, between 150 and 500 angstroms, between 50 and 500 angstroms, or within another similar range.

In some embodiments, the conformal conductive glue layer 502 is or comprises one or more of tantalum (Ta), tantalum nitride (TaN), or the like. In some embodiments, the underlying wire 202a is or comprises an conductive material, such as copper (Cu), tungsten (W), aluminum (Al), or the like. In some embodiments, the conformal conductive glue layer 502 and the first conductive layer 504 are formed using a deposition process, such as atomic layer deposition (ALD), physical vapor deposition (PVD), chemical vapor deposition (CVD), or the like.

As shown in cross-sectional view 1700 of FIG. 17, the first conformal dielectric layer 602, the second conformal dielectric layer 604, and the third conformal dielectric layer 606 are formed over the first conductive layer 504 and in the first openings 1506. In some embodiments, the first conformal dielectric layer 602 and the third conformal dielectric layer 606 independently are or comprise an insulative materials with a high dielectric constant (e.g., a dielectric constant that is over approximately 150), such as strontium titanate (Sr_{w}Ti_{y}O_{z}, as described in relation to FIG. 6), barium titanate (BaₓTi_{y}O_{z}, as described in relation to FIG. 6), strontium barium titanate (Sr_{w}BaₓTi_{y}O_{z}, as described in relation to FIG. 6), or the like. In some embodiments, the second conformal dielectric layer 604 is or comprises an insulative material with a dielectric constant less than a fifth of the dielectric constants of the first conformal dielectric layer 602 and the third conformal dielectric layer 606, such as zirconium oxide (ZrO₂), hafnium oxide (HfO₂), aluminum oxide (Al₂O₃), hafnium aluminum oxide, zirconium aluminum oxide, or the like. In some embodiments, the first conformal dielectric layer 602, the second conformal dielectric layer 604, and the third conformal dielectric layer 606 are formed using a deposition process, such as ALD, PVD, CVD, or the like.

In some embodiments, the first conformal dielectric layer 602 has a thickness approximately between 1 to 80 angstroms, between 30 and 100 angstroms, between 1 and 100 angstroms, or within another similar range. In some embodiments, the second conformal dielectric layer 604 has a thickness approximately between 1 to 40 angstroms, between 10 and 50 angstroms, between 1 and 50 angstroms, or within another similar range. In some embodiments, the third conformal dielectric layer 606 has a thickness approximately between 1 to 80 angstroms, between 30 and 100 angstroms, between 1 and 100 angstroms, or within another similar range.

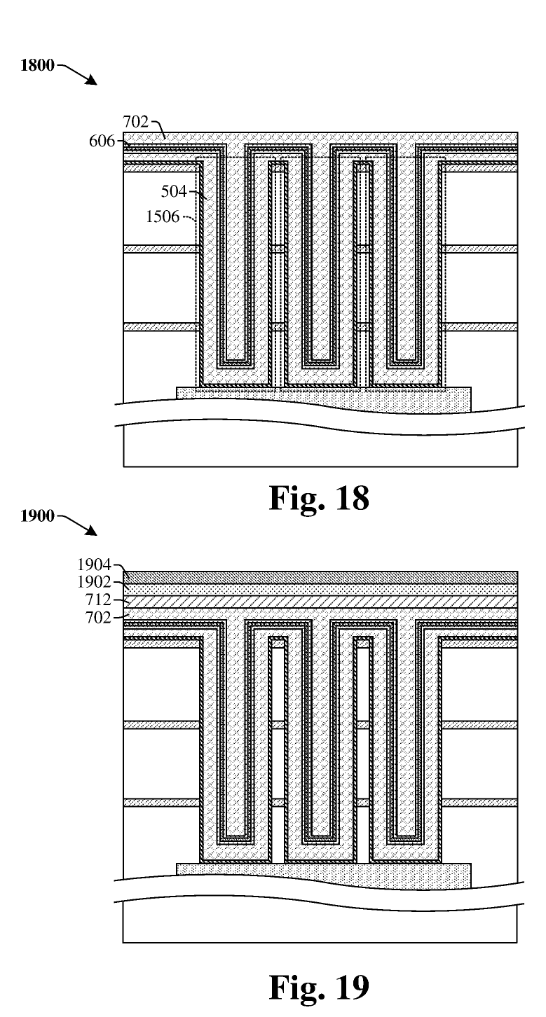

As shown in cross-sectional view 1800 of FIG. 18, the second conductive layer 702 is formed over the third conformal dielectric layer 606, filling the first openings 1506 (shown in phantom). In some embodiments, the second conductive layer 702 is or comprises a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the second conductive layer 702 has a thickness within the same range as the range of thicknesses for the first conductive layer 504. In some embodiments, the second conductive layer 702 is formed using a deposition process such as ALD, PVD, CVD, or the like.

As shown in cross-sectional view 1900 of FIG. 19, in some embodiments, a first conformal capping layer 712, a second conformal capping layer 1902, and a third conformal capping layer 1904 are formed over the second conductive layer 702. In other embodiments, the third conformal capping layer 1904 and/or the second conformal capping layer 1902 are omitted, resulting in one or two conformal capping layers being formed on the second conductive layer 702. In some embodiments, the first conformal capping layer 712, the second conformal capping layer 1902, and the third conformal capping layer 1904 independently are or comprise insulative materials such as silicon dioxide (SiO₂), silicon nitride (Si₃N₄), silicon oxynitride, or the like. In some embodiments, the first conformal capping layer 712, the second conformal capping layer 1902, and the third conformal capping layer 1904, are formed using deposition processes such as ALD, PVD, CVD, or the like.

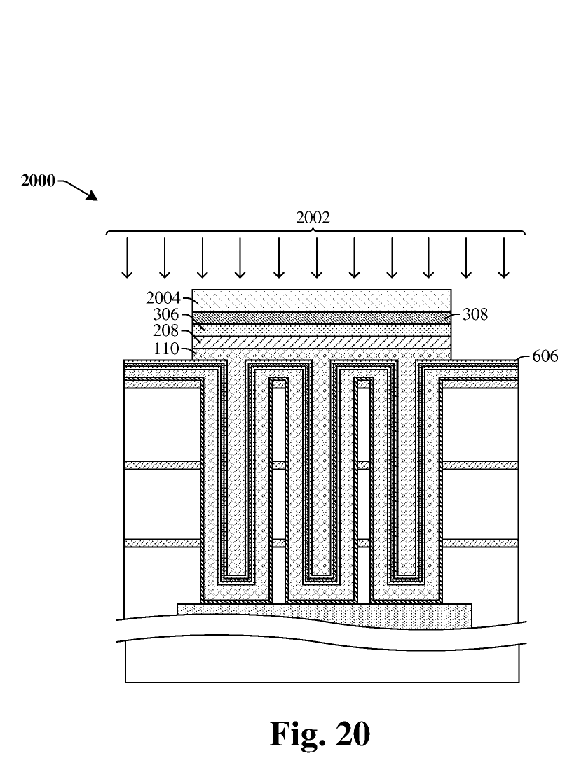

As shown in cross-sectional view 2000 of FIG. 20, a fifth masking layer 2004 is formed over the third conformal capping layer (see 1904 of FIG. 19). In some embodiments, the fifth masking layer 2004 is or comprises a photoresist, hard mask, or the like. In some embodiments, the fifth masking layer 2004 is formed using a deposition process, dipping process, spin-on process, sputtering process, or the like. The fifth masking layer 2004 is subsequently patterned to cover an area of the second conductive layer (see 702 of FIG. 18) corresponding to the area of the second electrode 110 and to expose surrounding portions of the third conformal capping layer (see 1904 of FIG. 19). In some embodiments, the fifth masking layer 2004 is patterned using an etching process, photolithography, or the like.

After the fifth masking layer 2004 is patterned, a fifth etching process 2002 is performed. The fifth etching process 2002 removes portions of the first conformal capping layer (see 712 of FIG. 19), the second conformal capping layer (see 1902 of FIG. 19), the third conformal capping layer (see 1904 of FIG. 19), and the second conductive layer (see 702 of FIG. 19) that extend past outer sidewalls of the second electrode 110, resulting in the second electrode 110, the first capping layer 208, the second capping layer 306, and the third capping layer 308 remaining. The fifth etching process 2002 also exposes the third conformal dielectric layer 606. In some embodiments, the fifth etching process 2002 is or comprises an anisotropic dry etching process. The fifth masking layer 2004 is subsequently removed.

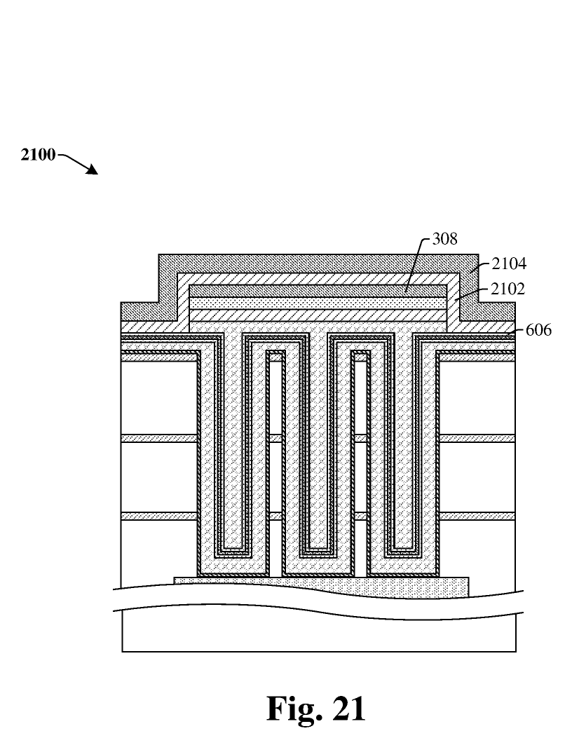

As shown in cross-sectional view 2100 of FIG. 21, a first conformal spacer layer 2102 and a second conformal spacer layer 2104 are formed over the third conformal dielectric layer 606 and the third capping layer 308. In some embodiments, the first conformal spacer layer 2102 and the second conformal spacer layer 2104 independently are or comprise insulative materials such as silicon dioxide (SiO₂), silicon nitride (Si₃N₄), silicon oxynitride, or the like. In some embodiments, the first conformal spacer layer 2102 and the second conformal spacer layer 2104 are formed using deposition processes such as ALD, PVD, CVD, or the like.

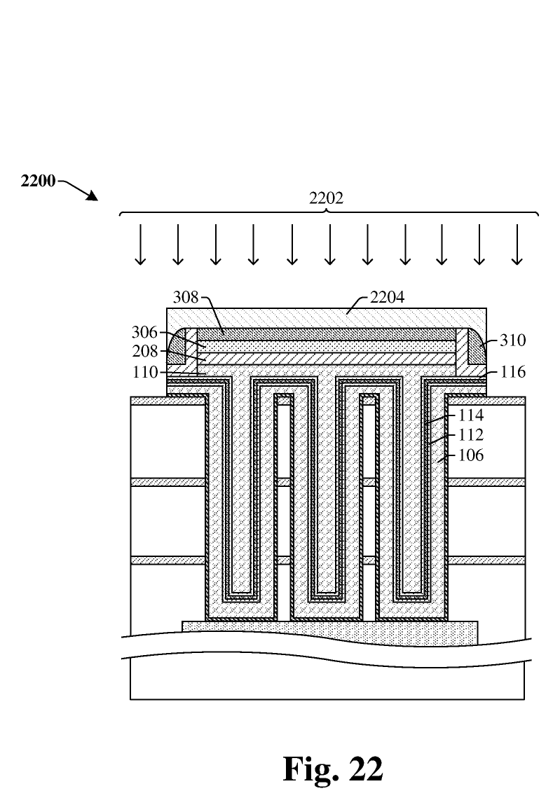

As shown in cross-sectional view 2200 of FIG. 22, a sixth etching process 2202 removes portions of the first conformal spacer layer 2102 and the second conformal spacer layer 2104, resulting in the insulative spacer 310 surrounding the first capping layer 208, the second capping layer 306, and the third capping layer 308. Portions of the first conformal dielectric layer (see 602 of FIG. 17), the second conformal dielectric layer (see 604 of FIG. 17), and the third conformal dielectric layer (see 606 of FIG. 17) are subsequently removed by additional etching processes. In some embodiments, an additional masking layer 2204 is formed over the insulative spacer 310 and the third capping layer 308 before the additional etching processes. The additional etching processes result in the first electrode 106, the first dielectric layer 112, the second dielectric layer 114, and the third dielectric layer 116 remaining on the substrate 104.

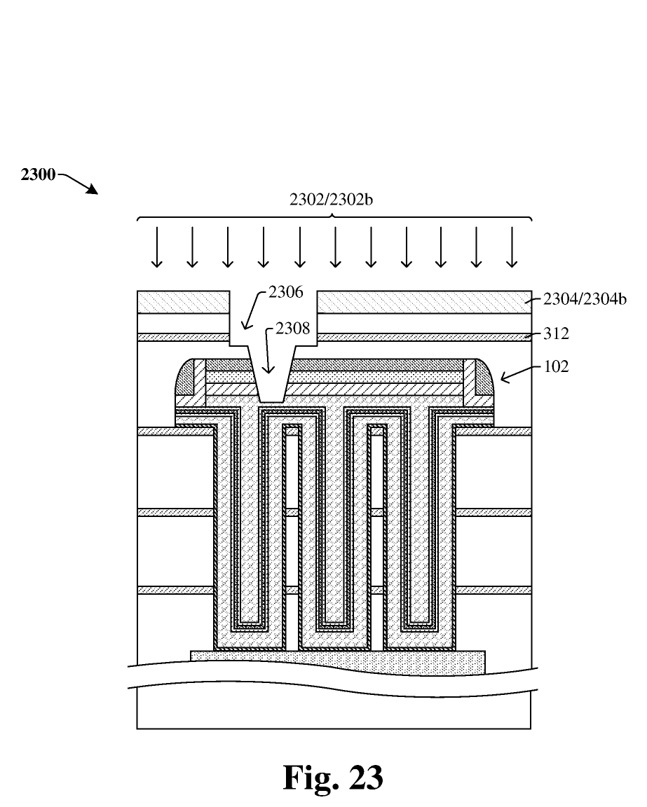

As shown in cross-sectional view 2300 of FIG. 23, additional layers of the interlayer dielectric 206 is deposited over the capacitor 102, and a second wire openings 2306 and second via openings 2308 are subsequently etched into the interlayer dielectric 206, exposing the second electrode 110. The additional layers of the interlayer dielectric 206 and the etch stop layers 312 are formed using deposition processes, such as ALD, PVD, CVD, or the like.

After the additional layers of the interlayer dielectric 206 are formed, a plurality of seventh etching processes 2302 are performed. The plurality of seventh etching processes 2302 are performed according to a plurality of sixth masking layers 2304, resulting in the second wire openings 2306 and the second via openings 2308. In some embodiments, a first mask (not shown) of the plurality of sixth masking layers 2304 is formed and patterned to expose portions of the interlayer dielectric 206 corresponding to the second via openings 2308. A first etch (not shown) of the plurality of seventh etching processes 2302 is performed to then form a portion of the second via openings 2308. The first mask is removed, and a second mask 2304b of the plurality of sixth masking layers 2304 is formed and patterned to expose portions of the interlayer dielectric 206 corresponding to the locations of the second wire openings 2306. A second etch 2302b of the plurality of seventh etching processes 2302 is performed to then open the remaining portion of the second via openings 2308 and the second wire openings 2306. In some embodiments, sacrificial plugs (not shown) are formed in the second via openings 2308 to reduce the effect of the second etch 2302b on the underlying second electrodes 110. The second mask 2304b is subsequently removed.

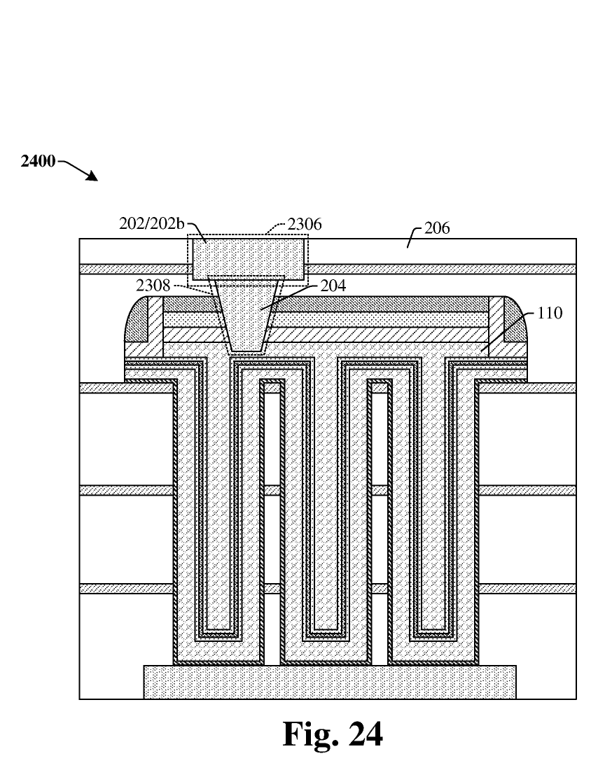

As shown in cross-sectional view 2400 of FIG. 24, the contacts 204 and an overlying wire 202b of the interconnect structure is formed in the first via openings 1208 (shown in phantom) and the first wire openings 1206 (shown in phantom). In some embodiments, the contacts 204 and an overlying wire 202b are formed using a deposition process such as ALD, PVD, CVD, or the like to form a conformal metal layer (not shown), then performing a planarization process (e.g., a chemical mechanical planarization (CMP) process to remove portions of the conformal metal layer extending over the interlayer dielectric 206. In some embodiments, the contacts 204 and an overlying wire 202b are or comprise a conductive metal, such as copper (Cu), tungsten (W), aluminum (Al), or the like. In some embodiments, a second conductive glue layer (not shown) is deposited before the conformal metal layer to separate the material of the contacts 204 and the overlying wire 202b from the first, second, and third electrodes 106, 110, 214.

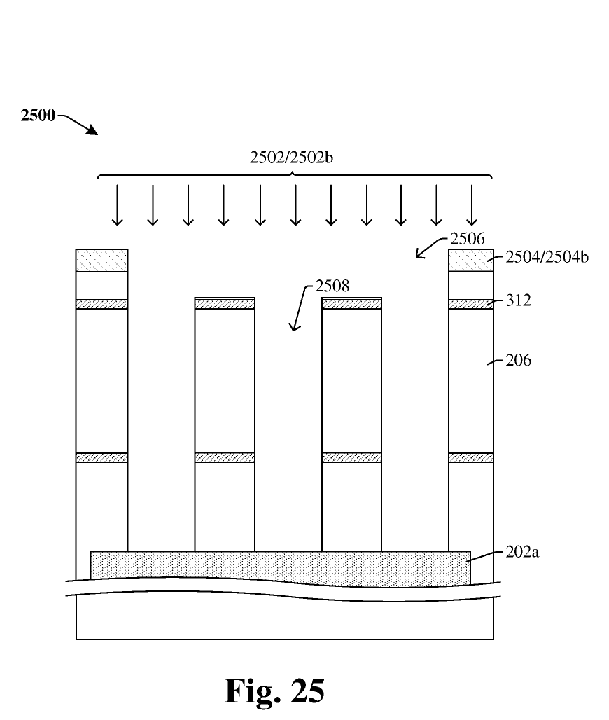

FIGS. 25-37 illustrate cross-sectional views 2500-3700 of some embodiments of a method of forming an integrated device having a three dimensional capacitor with an insulator stack comprising a first high-k insulator, a first high band gap insulator, and a second high-k insulator extending into a plurality of openings. For example, the method described may be used to form the integrated device described in relation to FIGS. 3C, 3D, and/or 3E. Although FIGS. 25-37 are described in relation to a method, it will be appreciated that the structures disclosed in FIGS. 25-37 are not limited to such a method, but instead may stand alone as structures independent of the method.

As shown in cross-sectional view 2500 of FIG. 25, the interlayer dielectric 206 and the etch stop layers 312 are deposited over the underlying wire 202a, and a first base portion opening 2506 and a first sleeve opening 2508 are subsequently etched into the interlayer dielectric 206, exposing the underlying wire 202a. The interlayer dielectric 206 and the etch stop layers 312 are formed using deposition processes, such as ALD, PVD, CVD, or the like.

After the interlayer dielectric 206 and the etch stop layers 312 are formed, a plurality of eighth etching processes 2502 are performed. The plurality of eighth etching processes 2502 are performed according to a plurality of seventh masking layers 2504, resulting in the first base portion opening 2506 and the first sleeve opening 2508. In some embodiments, a first mask (not shown) of the plurality of seventh masking layers 2504 is formed and patterned to expose portions of the interlayer dielectric 206 corresponding to the first sleeve opening 2508. A first etch (not shown) of the plurality of eighth etching processes 2502 is performed to then form a portion of the first sleeve opening 2508. The first mask is removed, and a second mask 2504b of the plurality of seventh masking layers 2504 is formed and patterned to expose portions of the interlayer dielectric 206 corresponding to the location of the first base portion opening 2506. A second etch 2502b of the plurality of eighth etching processes 2502 is performed to then open the remaining portion of the first sleeve opening 2508 and the first base portion opening 2506. In some embodiments, sacrificial plugs (not shown) are formed in the first sleeve opening 2508 to reduce the effect of the second etch 2302b on the underlying wire 202a. The second mask 2504b is subsequently removed. After the plurality of eighth etching processes 2502, the remaining portions of the interlayer dielectric 206 beneath the first base portion opening 2506 have circular profiles when viewed from a top down perspective.

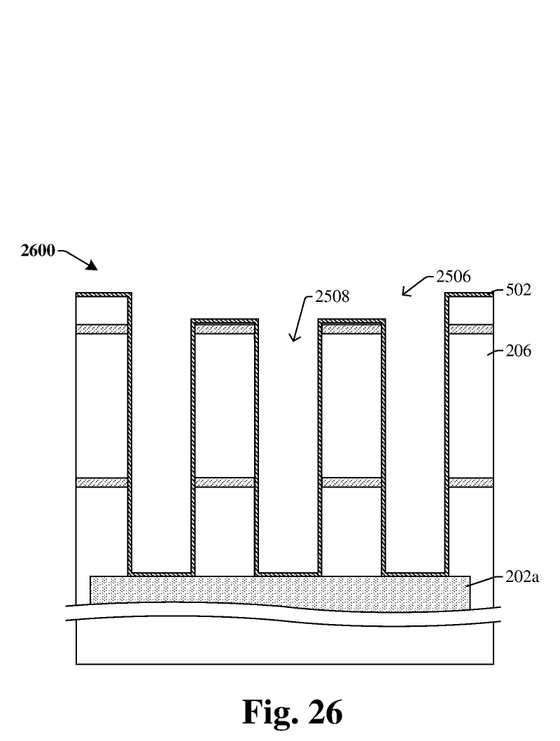

As shown in cross-sectional view 2600 of FIG. 26, the conformal conductive glue layer 502 is formed over the interlayer dielectric 206 and in the first sleeve opening 2508 and the first base portion opening 2506. The conformal conductive glue layer 502 is electrically coupled to the underlying wire 202a. The conformal conductive glue layer 502 covers upper surfaces of the portions of the interlayer dielectric 206 with circular profiles. In some embodiments, the conformal conductive glue layer 502 is or comprises one or more of tantalum (Ta), tantalum nitride (TaN), or the like. In some embodiments, the conformal conductive glue layer 502 is formed using a deposition process, such as ALD, PVD, CVD, or the like.

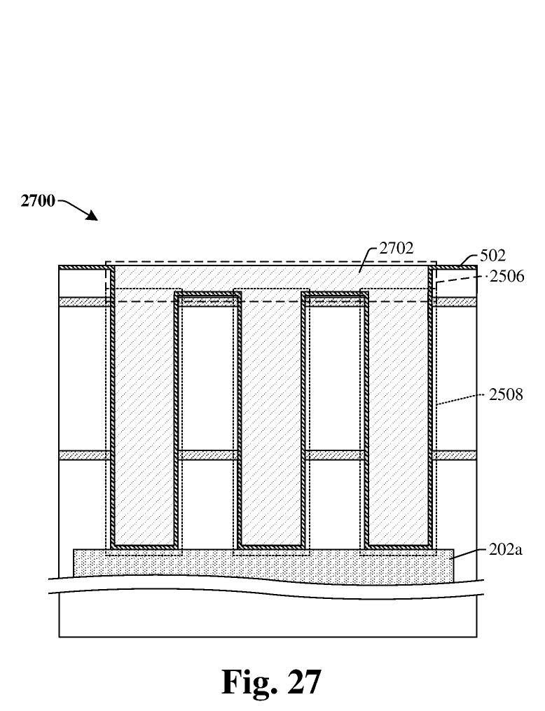

As shown in cross-sectional view 2700 of FIG. 27, a first sacrificial fill layer 2702 is formed within the first sleeve opening 2508 and the first base portion opening 2506. In some embodiments, the first sacrificial fill layer 2702 is or comprises an insulative material, such as silicon dioxide (SiO₂) or the like. In some embodiments, the first sacrificial fill layer 2702 is formed using a deposition process, such as ALD, PVD, CVD, or the like. After the first sacrificial fill layer 2702 is formed, portions of the first sacrificial fill layer 2702 above an uppermost surface of the conformal conductive glue layer 502 are removed. In some embodiments, the portions of the first sacrificial fill layer 2702 are removed using a planarization process (e.g., a CMP process).

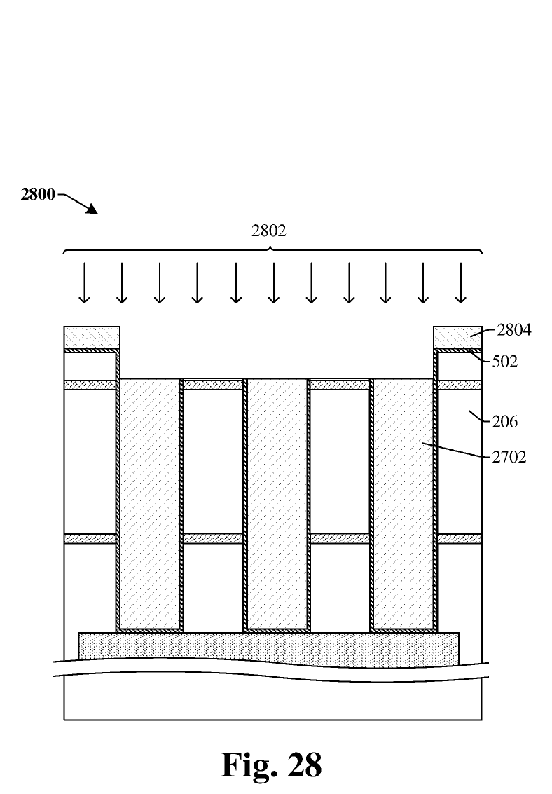

As shown in cross-sectional view 2800 of FIG. 28, an eighth masking layer 2804 is formed over the conformal conductive glue layer 502. In some embodiments, the eighth masking layer 2804 is or comprises a photoresist, hard mask, or the like. In some embodiments, the eighth masking layer 2804 is formed using a deposition process, dipping process, spin-on process, sputtering process, or the like. The eighth masking layer 2804 is subsequently patterned to cover an area of the conformal conductive glue layer 502 surrounding the first base portion opening 2506. In some embodiments, the eighth masking layer 2804 is patterned using an etching process, photolithography, or the like.

After the eighth masking layer 2804 is patterned, a ninth etching process 2802 is performed. The ninth etching process 2802 removes portions of the interlayer dielectric 206, the first sacrificial fill layer 2702, and the conformal conductive glue layer 502, resulting in inner and outer sidewalls of the conformal conductive glue layer 502 having concentric circular profiles when viewed from a top-down perspective (see the cylindrical structures 222a of FIG. 3D). In some embodiments, portions of the etch stop layer 312 closest to the first base portion opening 2506 are also removed by the ninth etching process 2802. In some embodiments, the ninth etching process 2802 is or comprises an anisotropic dry etching process. The eighth masking layer 2804 is subsequently removed.

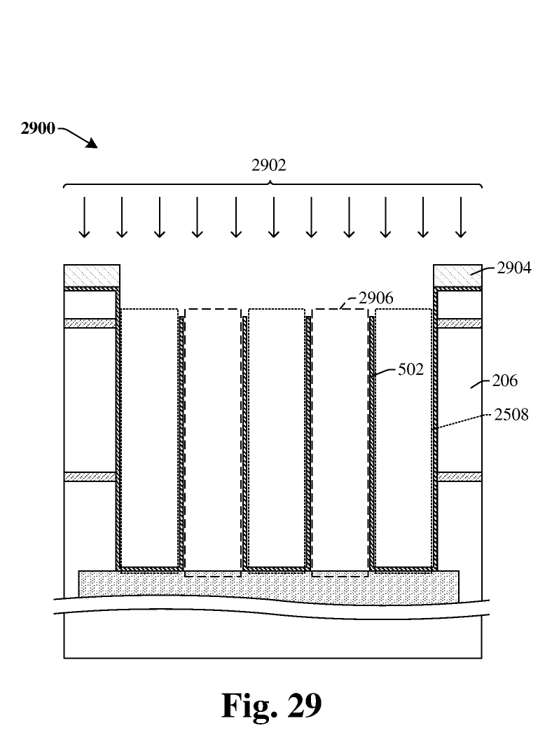

As shown in cross-sectional view 2900 of FIG. 29, in some embodiments, a ninth masking layer 2904 is formed over the conformal conductive glue layer 502. In some embodiments, the ninth masking layer 2904 is or comprises a photoresist, hard mask, or the like. In some embodiments, the ninth masking layer 2904 is formed using a deposition process, dipping process, spin-on process, sputtering process, or the like. The ninth masking layer 2904 is subsequently patterned to cover an area of the conformal conductive glue layer 502 surrounding the first base portion opening 2506. In some embodiments, the ninth masking layer 2904 is patterned using an etching process, photolithography, or the like.

After the ninth masking layer 2904 is patterned, a tenth etching process 2902 is performed. In some embodiments, the tenth etching process 2902 removes portions of the interlayer dielectric 206, resulting in second sleeve openings 2906 separated from the first sleeve opening 2508 by the conformal conductive glue layer 502 and the underlying wire 202a being exposed. In some embodiments, the tenth etching process 2902 is or comprises an anisotropic dry etching process. In other embodiments, the tenth etching process 2902 is or comprises are selective wet etching process that targets the material of the interlayer dielectric 206 and the first sacrificial fill layer 2702 without substantially etching the conformal conductive glue layer 502. In some embodiments using the selective etch, the ninth masking layer 2904 is omitted. After the tenth etching process 2902 ninth masking layer 2904 is removed if present.

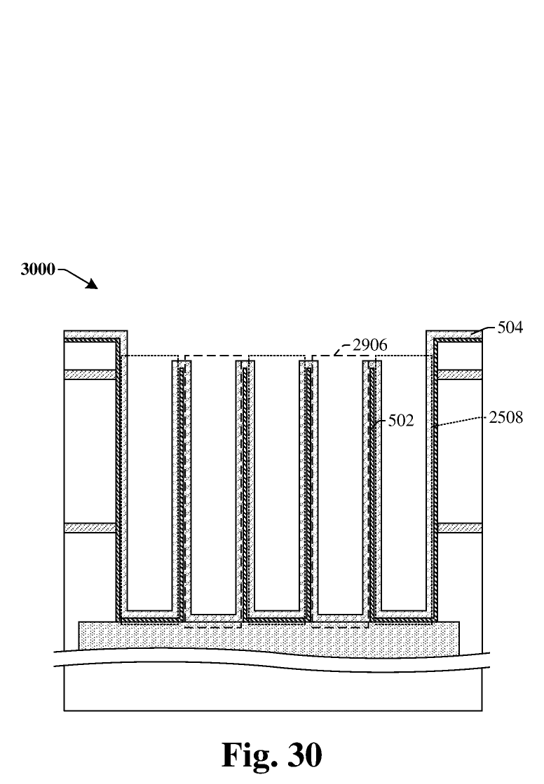

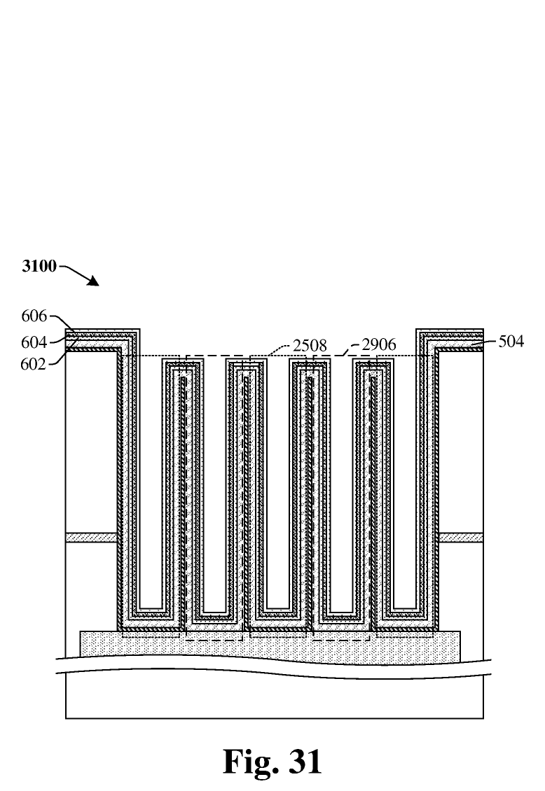

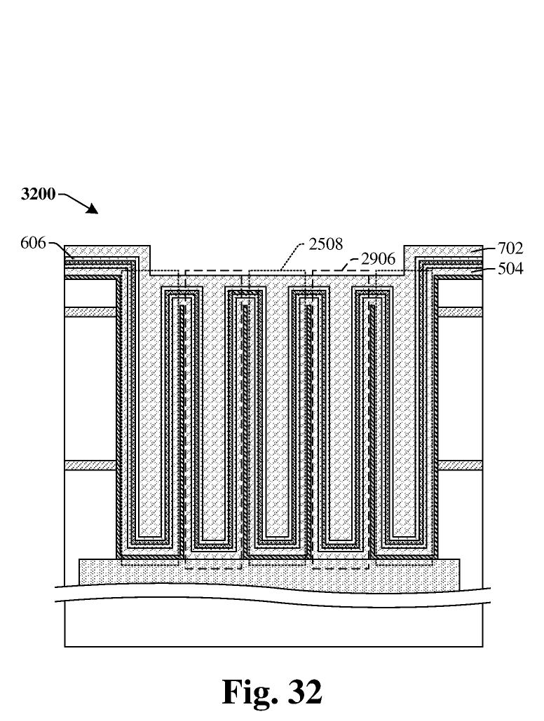

As shown in cross-sectional view 3000 of FIG. 30, the first conductive layer 504 is formed over the interlayer dielectric 206 and in the first sleeve opening 2508 and the second sleeve openings 2906. The first conductive layer 504 covers sidewalls of the conformal conductive glue layer 502. In some embodiments, the first conductive layer 504 is or comprises a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the first conductive layer 504 has a thickness approximately between 50 to 400 angstroms, between 150 and 500 angstroms, between 50 and 500 angstroms, or within another similar range. In some embodiments, the first conductive layer 504 is formed using a deposition process, such as ALD, PVD, CVD, or the like.

As shown in cross-sectional view 3100 of FIG. 31, the first conformal dielectric layer 602, the second conformal dielectric layer 604, and the third conformal dielectric layer 606 are formed over the first conductive layer 504 and in the first sleeve opening 2508 and the second sleeve openings 2906. In some embodiments, the first conformal dielectric layer 602 and the third conformal dielectric layer 606 independently are or comprise an insulative materials with a high dielectric constant (e.g., a dielectric constant that is over approximately 150), such as strontium titanate (Sr_{w}Ti_{y}O_{z}, as described in relation to FIG. 6), barium titanate (BaₓTi_{y}O_{z}, as described in relation to FIG. 6), strontium barium titanate (Sr_{w}BaₓTi_{y}O_{z}, as described in relation to FIG. 6), or the like. In some embodiments, the second conformal dielectric layer 604 is or comprises an insulative material with a dielectric constant less than a fifth of the dielectric constants of the first conformal dielectric layer 602 and the third conformal dielectric layer 606, such as zirconium oxide (ZrO₂), hafnium oxide (HfO₂), aluminum oxide (Al₂O₃), hafnium aluminum oxide, zirconium aluminum oxide, or the like. In some embodiments, the first conformal dielectric layer 602, the second conformal dielectric layer 604, and the third conformal dielectric layer 606 are formed using a deposition process, such as ALD, PVD, CVD, or the like.

In some embodiments, the first conformal dielectric layer 602 has a thickness approximately between 1 to 80 angstroms, between 30 and 100 angstroms, between 1 and 100 angstroms, or within another similar range. In some embodiments, the second conformal dielectric layer 604 has a thickness approximately between 1 to 40 angstroms, between 10 and 50 angstroms, between 1 and 50 angstroms, or within another similar range. In some embodiments, the third conformal dielectric layer 606 has a thickness approximately between 1 to 80 angstroms, between 30 and 100 angstroms, between 1 and 100 angstroms, or within another similar range.

As shown in cross-sectional view 3200 of FIG. 32, the second conductive layer 702 is formed over the third conformal dielectric layer 606, filling the first sleeve opening 2508 (shown in phantom) and the second sleeve openings 2906 (shown in phantom). In some embodiments, the second conductive layer 702 is or comprises a conductive material that has or is treated to have a work function greater than 4.9, such as nickel (Ni), palladium (Pd), iridium (Ir), ruthenium (Ru), platinum (Pt), ruthenium oxide (RuO₂), molybdenum nitride (Mo₂N), tungsten nitride (WN₂), a combination of the foregoing, or the like. In some embodiments, the second conductive layer 702 has a thickness within the same range as the range of thicknesses for the first conductive layer 504. In some embodiments, the second conductive layer 702 is formed using a deposition process such as ALD, PVD, CVD, or the like.

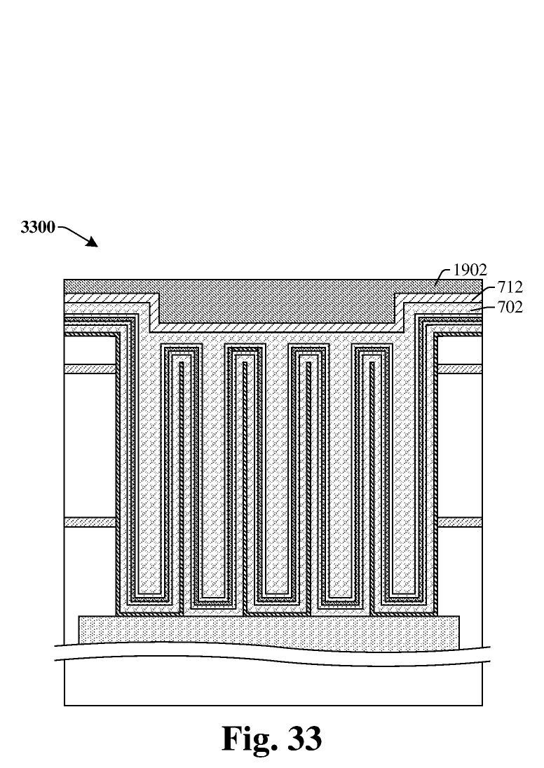

As shown in cross-sectional view 3300 of FIG. 33, in some embodiments, a first conformal capping layer 712 and a second conformal capping layer 1902 are formed over the second conductive layer 702. In some embodiments, the first conformal capping layer 712 and the second conformal capping layer 1902 independently are or comprise insulative materials such as silicon dioxide (SiO₂), silicon nitride (Si₃N₄), silicon oxynitride, or the like. In some embodiments, the first conformal capping layer 712 and the second conformal capping layer 1902 are formed using deposition processes such as ALD, PVD, CVD, or the like.

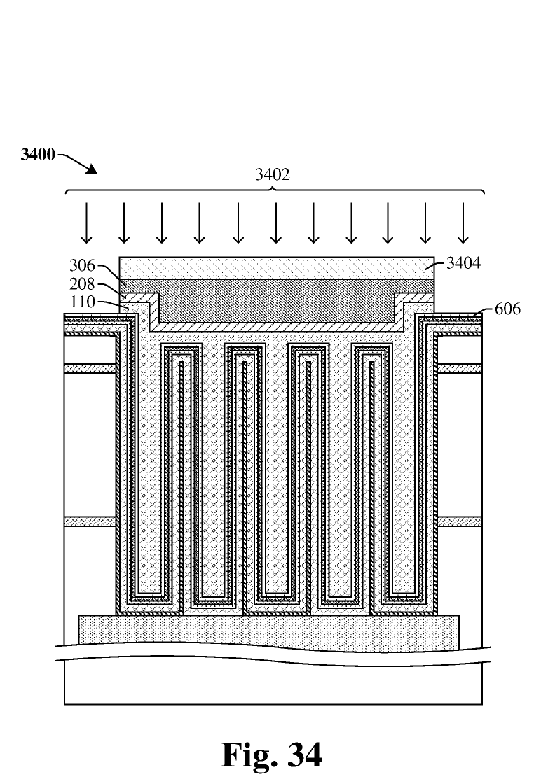

As shown in cross-sectional view 3400 of FIG. 34, a tenth masking layer 3404 is formed over the second conformal capping layer (see 1902 of FIG. 33). In some embodiments, the tenth masking layer 3404 is or comprises a photoresist, hard mask, or the like. In some embodiments, the tenth masking layer 3404 is formed using a deposition process, dipping process, spin-on process, sputtering process, or the like. The tenth masking layer 3404 is subsequently patterned to cover an area of the second conformal capping layer (see 1902 of FIG. 33) corresponding to the area of the second electrode 110 and to expose surrounding portions of the second conformal capping layer (see 1902 of FIG. 33). In some embodiments, the tenth masking layer 3404 is patterned using an etching process, photolithography, or the like.

After the tenth masking layer 3404 is patterned, a eleventh etching process 3402 is performed. The eleventh etching process 3402 removes portions of the first conformal capping layer (see 712 of FIG. 19), the second conformal capping layer (see 1902 of FIG. 19), and the second conductive layer (see 702 of FIG. 32) that extend past outer sidewalls of the second electrode 110, resulting in the first capping layer 208, the second capping layer 306, and the second electrode 110 remaining on the second conductive layer 702. The eleventh etching process 3402 also exposes the third conformal dielectric layer 606. In some embodiments, the eleventh etching process 3402 is or comprises an anisotropic dry etching process. The tenth masking layer 3404 is subsequently removed.

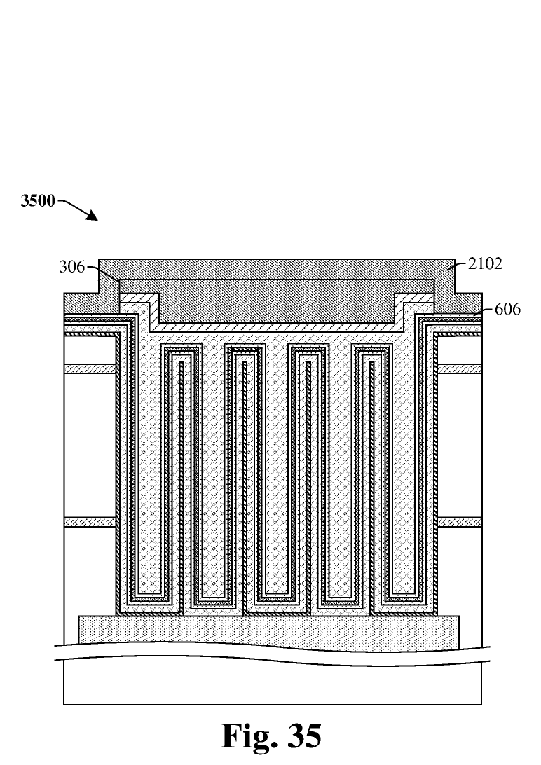

As shown in cross-sectional view 3500 of FIG. 35, a first conformal spacer layer 2102 is formed over the second capping layer 306 and the third conformal dielectric layer 606. In some embodiments, the first conformal spacer layer 2102 is or comprises and insulative material such as silicon dioxide (SiO₂), silicon nitride (Si₃N₄), silicon oxynitride, or the like. In some embodiments, the first conformal spacer layer 2102 is formed using a deposition process such as ALD, PVD, CVD, or the like.

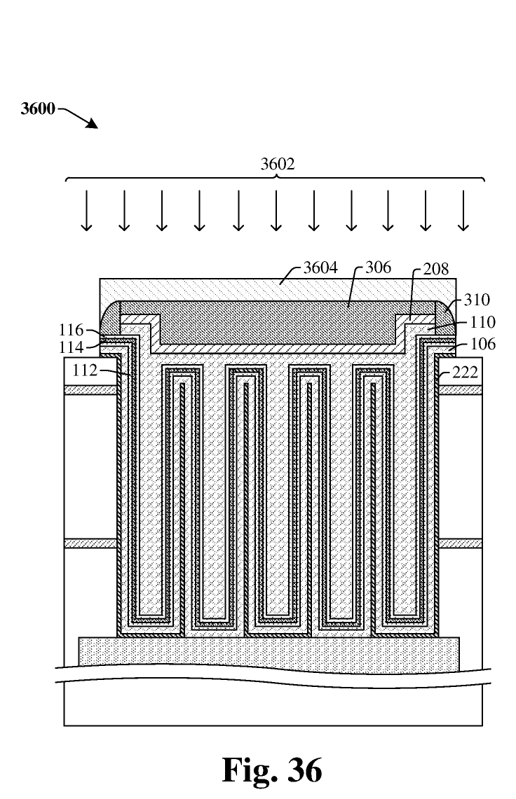

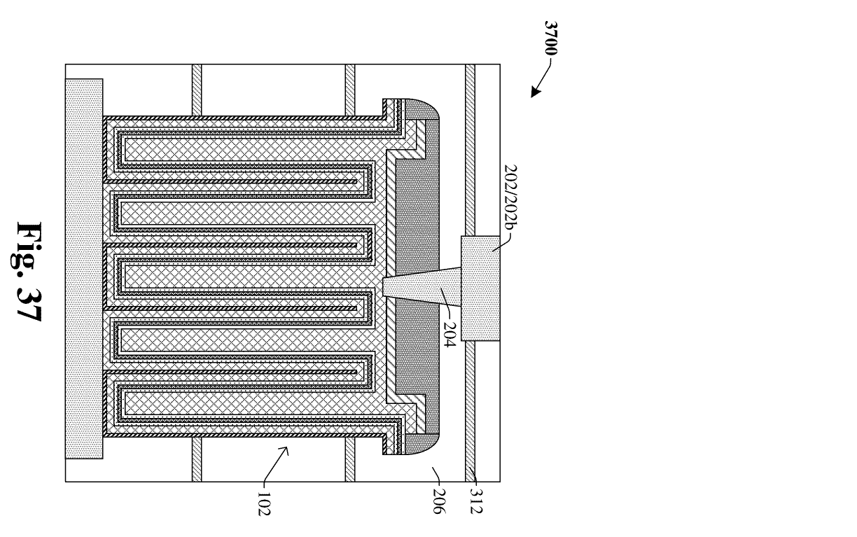

As shown in cross-sectional view 3600 of FIG. 36, a twelfth etching process 3602 removes portions of the first conformal spacer layer 2102, resulting in the insulative spacer 310 surrounding the first capping layer 208, the second capping layer 306, and the second electrode 110. Portions of conformal conductive glue layer (see 502 of FIG. 30) the first conductive layer (see 504 of FIG. 30), the first conformal dielectric layer (see 602 of FIG. 31), the second conformal dielectric layer (see 604 of FIG. 31), the third conformal dielectric layer (see 606 of FIG. 31) are subsequently removed by additional etching processes. In some embodiments, an additional masking layer 3604 is formed over the insulative spacer 310 and the second capping layer 306 before the additional etching processes. The additional etching processes result in the conductive glue layer 222, the first electrode 106, the first dielectric layer 112, the second dielectric layer 114, and the third dielectric layer 116 remaining on the substrate 104.

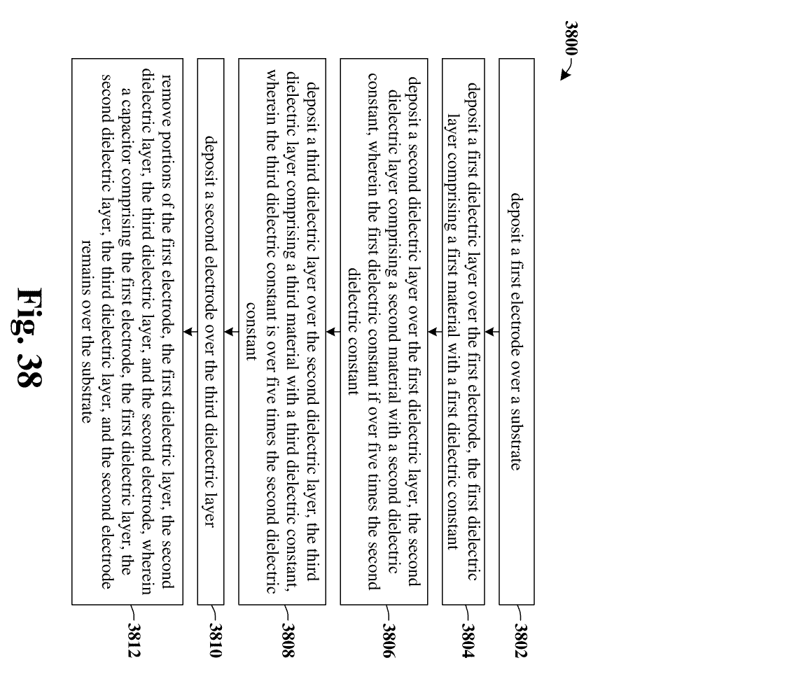

As shown in cross-sectional view 3700 of FIG. 37, additional layers of the interlayer dielectric 206 and the etch stop layers 312 are deposited over the capacitor 102, and the contacts 204 and the overlying wire 202b are formed over the capacitor 102 using techniques substantially the same as those described in relation to FIGS. 23 and 24.

FIG. 38 illustrates a flow diagram 3800 of some embodiments of a method of forming an integrated device having capacitor with a first insulator stack comprising a first high-k insulator, a first high band gap insulator, and a second high-k insulator.

While method 3800 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 3802, a first electrode is deposited over a substrate. FIGS. 5, 16 and 30 illustrate cross-sectional views 500, 1600, 3000 of some embodiments corresponding to act 3802.

At 3804, a first dielectric layer is deposited over the first electrode, the first dielectric layer comprising a first material with a first dielectric constant. FIGS. 6, 17 and 31 illustrate cross-sectional views 600, 1700, 3100 of some embodiments corresponding to act 3804.

At 3806, a second dielectric layer is deposited over the first dielectric layer, the second dielectric layer comprising a second material with a second dielectric constant, wherein the first dielectric constant if over five times the second dielectric constant. FIGS. 6, 17 and 31 illustrate cross-sectional views 600, 1700, 3100 of some embodiments corresponding to act 3806.

At 3808, a third dielectric layer is deposited over the second dielectric layer, the third dielectric layer comprising a third material with a third dielectric constant, wherein the third dielectric constant is over five times the second dielectric constant. FIGS. 6, 17 and 31 illustrate cross-sectional views 600, 1700, 3100 of some embodiments corresponding to act 3808.

At 3810, a second electrode is deposited over the third dielectric layer. FIGS. 7, 18 and 32 illustrate cross-sectional views 700, 1800, 3200 of some embodiments corresponding to act 3810.

At 3812, portions of the first electrode, the first dielectric layer, the second dielectric layer, the third dielectric layer, and the second electrode, wherein a capacitor comprising the first electrode, the first dielectric layer, the second dielectric layer, the third dielectric layer, and the second electrode remains over the substrate. FIGS. 8-10, 20-22 and 34-36 illustrate cross-sectional views 800-1000, 2000-2200, 3400-3600 of some embodiments corresponding to act 3812.

Therefore, the present disclosure relates to improved capacitor structure that increases capacitance and reduces current leakage without increasing the size of the integrated device.

Accordingly, in some embodiments, the present disclosure relates to an integrated device, including: a first electrode over a substrate; a first dielectric layer on the first electrode and having a first material with a first dielectric constant; a second dielectric layer on the first dielectric layer having a second material with a second dielectric constant, where the first dielectric constant is over 5 times the second dielectric constant; a third dielectric layer on the second dielectric layer having a third material with a third dielectric constant, where the third dielectric constant is over 5 times the second dielectric constant; and a second electrode separated from the first electrode by the first dielectric layer, the second dielectric layer, and the third dielectric layer.

In other embodiments, the present disclosure relates to a method of forming an integrated device, including: depositing a first electrode over a substrate; depositing a first dielectric stack, further including: depositing a first dielectric layer over the first electrode, the first dielectric layer comprising a first material with a first dielectric constant; depositing a second dielectric layer over the first dielectric layer, the second dielectric layer comprising a second material with a second dielectric constant, where the first dielectric constant if over five times the second dielectric constant; and depositing a third dielectric layer over the second dielectric layer, the third dielectric layer comprising a third material with a third dielectric constant, where the third dielectric constant is over five times the second dielectric constant; depositing a second electrode over the third dielectric layer; and removing portions of the first electrode, the first dielectric layer, the second dielectric layer, the third dielectric layer, and the second electrode, where a capacitor comprising the first electrode, the first dielectric layer, the second dielectric layer, the third dielectric layer, and the second electrode remains over the substrate.

In yet other embodiments, the present disclosure relates to a method of forming an integrated device, including: depositing a first electrode over a substrate; depositing a first dielectric stack, further including: depositing a first dielectric layer over the first electrode, the first dielectric layer including a first material with a first band gap having a first conduction band energy; depositing a second dielectric layer over the first dielectric layer, the second dielectric layer including a second material with a second band gap having a second conduction band energy, where the second conduction band energy is over 1 electron volt greater than the first conduction band energy; and depositing a third dielectric layer over the second dielectric layer, the third dielectric layer including a third material with a third band gap having a third conduction band energy, where the second conduction band energy is over 1 electron volt greater than the third conduction band energy; depositing a second electrode over the third dielectric layer; removing portions of the first electrode, the first dielectric layer, the second dielectric layer, the third dielectric layer, and the second electrode, where a capacitor comprising the first electrode, the first dielectric layer, the second dielectric layer, the third dielectric layer, and the second electrode remains over the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a first electrode over a substrate;
a first dielectric layer on the first electrode and comprising a first material with a first dielectric constant;
a second dielectric layer on the first dielectric layer and comprising a second material with a second dielectric constant, wherein the first dielectric constant is over 5 times the second dielectric constant;
a third dielectric layer on the second dielectric layer and comprising a third material with a third dielectric constant, wherein the third dielectric constant is over 5 times the second dielectric constant; and
a second electrode separated from the first electrode by the first dielectric layer, the second dielectric layer, and the third dielectric layer.

2. The integrated device of claim 1, wherein the first electrode and the second electrode comprise a conductive material with a work function greater than 4.9 volts.

3. The integrated device of claim 2, wherein the first electrode and the second electrode comprise one of nickel, ruthenium oxide, ruthenium, platinum, or tungsten nitride.

4. The integrated device of claim 2, wherein the first material and the third material have conduction band energies at least 1 eV greater than fermi levels of the first electrode and the second electrode.

5. The integrated device of claim 1, wherein the first material and the third material have perovskite crystalline structures, and wherein the second material is a conductive oxide.

6. The integrated device of claim 2, wherein the first dielectric constant and the third dielectric constant are greater than 150, and wherein the second dielectric constant is greater than 20.

7. A method of forming an integrated device, comprising:
depositing a first electrode over a substrate;
depositing a first dielectric stack, further comprising:
depositing a first dielectric layer over the first electrode, the first dielectric layer comprising a first material with a first dielectric constant;
depositing a second dielectric layer over the first dielectric layer, the second dielectric layer comprising a second material with a second dielectric constant, wherein the first dielectric constant is over five times the second dielectric constant; and
depositing a third dielectric layer over the second dielectric layer, the third dielectric layer comprising a third material with a third dielectric constant, wherein the third dielectric constant is over five times the second dielectric constant;
depositing a second electrode over the third dielectric layer; and
removing portions of the first electrode, the first dielectric layer, the second dielectric layer, the third dielectric layer, and the second electrode, wherein a capacitor comprising the first electrode, the first dielectric layer, the second dielectric layer, the third dielectric layer, and the second electrode remains over the substrate.

8. The method of claim 7, further comprising:
depositing an interlayer dielectric over the substrate before forming the first electrode; and
etching a plurality of openings into the interlayer dielectric, wherein the first electrode, the first dielectric layer, the second dielectric layer, the third dielectric layer, and the second electrode extend into the plurality of openings.

9. The method of claim 8, further comprising:
forming a first portion of an interconnect structure over the substrate comprising a first wire before depositing the interlayer dielectric, wherein etching the plurality of openings exposes the first wire; and
depositing a conductive glue layer over the interlayer dielectric and into the plurality of openings, wherein the conductive glue layer spaces the first electrode from the first wire and the interlayer dielectric.

10. The method of claim 8, wherein the plurality of openings comprise first sleeve openings and second sleeve openings, wherein the first sleeve openings extend to an underlying wire and wherein the second sleeve openings are spaced from the underlying wire by the interlayer dielectric.

11. The method of claim 8, wherein etching the plurality of openings further comprises:
etching a first plurality of openings into the interlayer dielectric, wherein remaining portions of the interlayer dielectric have a substantially circular profile when viewed from a top-down perspective;
depositing a conductive glue layer into the plurality of openings and across an upper surface of the interlayer dielectric;
removing portions of the conductive glue layer extending across the upper surface of the interlayer dielectric; and
etching a second plurality of openings by removing portions of the interlayer dielectric remaining on outer sidewalls of remaining portions of the conductive glue layer.

12. The method of claim 11, wherein the first electrode, the first dielectric layer, the second dielectric layer, the third dielectric layer, and the second electrode extend along inner and outer sidewalls of the conductive glue layer.

13. A method of forming an integrated device, comprising:
depositing a first electrode over a substrate;
depositing a first dielectric stack, further comprising:
depositing a first dielectric layer over the first electrode, the first dielectric layer comprising a first material with a first band gap having a first conduction band energy;
depositing a second dielectric layer over the first dielectric layer, the second dielectric layer comprising a second material with a second band gap having a second conduction band energy, wherein the second conduction band energy is over 1 electron volt greater than the first conduction band energy; and
depositing a third dielectric layer over the second dielectric layer, the third dielectric layer comprising a third material with a third band gap having a third conduction band energy, wherein the second conduction band energy is over 1 electron volt greater than the third conduction band energy;
depositing a second electrode over the third dielectric layer; and
removing portions of the first electrode, the first dielectric layer, the second dielectric layer, the third dielectric layer, and the second electrode, wherein a capacitor comprising the first electrode, the first dielectric layer, the second dielectric layer, the third dielectric layer, and the second electrode remains over the substrate.

14. The method of claim 13, wherein the first material and the third material have a first and third dielectric constant, respectively, and wherein the second material has a second dielectric constant that is less than a fifth of the first dielectric constant and the third dielectric constant.

15. The method of claim 13, wherein the first electrode comprises a conductive oxide with a work function greater than 4.9.

16. The method of claim 13, further comprising:
forming a second dielectric stack with an additional first dielectric layer comprising the first material, an additional second dielectric layer comprising the second material, and an additional third dielectric layer comprising the third material over the second electrode before removing portions of the second electrode;
forming a third electrode over the second dielectric stack; and
removing portions of the third electrode, wherein portions of the second electrode and the first electrode extend past outer sidewalls of the third electrode, and wherein portions of the first electrode extend past outer sidewalls of the second electrode.

17. The method of claim 13, further comprising forming a second dielectric stack with an additional first dielectric layer with substantially the same thickness and materials as the first dielectric layer, an additional second dielectric layer with substantially the same thickness and materials as the second dielectric layer, an additional third dielectric layer with substantially the same thickness and materials as the third dielectric layer over the first dielectric stack before forming the second electrode.

18. The method of claim 13, wherein the first dielectric layer, the second dielectric layer, and the third dielectric layer have thicknesses that are substantially equal.

19. The method of claim 13, wherein the first dielectric layer and the second dielectric layer have thicknesses that are substantially equal and that are greater than a thickness of the third dielectric layer.

20. The method of claim 13, wherein the first dielectric layer and the second dielectric layer have thicknesses that are substantially equal and that are less than a thickness of the third dielectric layer.
